(19) United States
(12) Patent Application Publication
(10) Pub. No.: US 2015/0252474 A1
(43) Pub. Date: Sep. 10, 2015

(54) SUBSTRATE PROCESSING APPARATUS, METHOD OF MANUFACTURING SEMICONDUCTOR DEVICE AND NON-TRANSITORY COMPUTER-READABLE RECORDING MEDIUM

(71) Applicant: Hitachi Kokusai Electric Inc., Tokyo (JP)

(72) Inventors: Hideharu ITATANI, Toyama-shi (JP); Tetsuaki INADA, Toyama-shi (JP); Motonari TAKEBAYASHI, Toyama-shi (JP); Kazuyuki TOYODA, Toyama-shi (JP)

(73) Assignee: Hitachi Kokusai Electric Inc., Tokyo (JP)

(21) Appl. No.: 14/640,589

(22) Filed: Mar. 6, 2015

(30) Foreign Application Priority Data
Mar. 6, 2014 (JP) 2014-043817
Jan. 30, 2015 (JP) 2015-016871

(51) Int. Cl. C23C 16/455; C23C 16/458; H01L 21/285; C23C 16/06; C23C 16/22; H01L 21/02; C23C 16/50; C23C 16/52

(52) U.S. Cl. CPC C23C 16/455; C23C 16/50; C23C 16/4584; C23C 16/52; C23C 16/06; C23C 16/22; H01L 21/02274; H01L 21/0262; H01L 21/28556

(57) ABSTRACT

A substrate processing apparatus includes: a process chamber including a source gas supply and a reactive gas supply to process a plurality of substrates in the source gas supply and the reactive gas supply; a substrate placement unit rotating in the process chamber, wherein the plurality of substrates are placed on the substrate placement unit along a rotational direction thereof; a plasma generator to generate plasma in plasma generation chamber installed an upper portion of the reactive gas supply; a coil wound along an outer circumference of the plasma generation chamber, a portion of which adjacent to a sidewall of the plasma generation chamber has a constant curvature; a reactive gas supply system to supply a reactive gas to the reactive gas supply via the plasma generation chamber through a ceiling of the plasma generation chamber; and a source gas supply system to supply a source gas.

### CROSS-REFERENCE TO RELATED PATENT APPLICATION

This non-provisional U.S. patent application claims priority under 35 U.S.C. §119 of Japanese Patent Application No. 2014-043817, filed on Mar. 6, 2014 and No. 2015-016871, filed on Jan. 30, 2015, the entire contents of which are hereby incorporated by reference.

### BACKGROUND OF THE INVENTION

1. Field of the Invention

The present invention relates to a substrate processing apparatus, a method of manufacturing a semiconductor device and a non-transitory computer-readable recording medium.

2. Description of the Related Art

As a method of forming a thin film that is used for a semiconductor device such as a flash memory or a dynamic random access memory (DRAM), a chemical vapor deposition (CVD) method or an alternate supply method has been known.

The CVD method is a method in which a gas-phase of a source gas and a reactive gas or a reaction at a surface of a substrate is used to deposit a thin film including an element of molecules of the source gas as a component on the substrate. Also, the alternate supply method is a method in which the source gas and the reactive gas are alternately supplied. A thinner film may be formed at a lower temperature in the alternate supply method than the CVD method.

Also, as a type of an apparatus for implementing the alternate supply method, for example, a vertical apparatus (refer to Patent document 1) in which laminated substrates are processed in a process chamber, a single wafer apparatus (refer to Patent document 2) in which substrates are processed one by one, or a rotary apparatus (refer to Patent document 3) in which a plurality of substrates are arranged in a circumferential direction, the substrate is rotated, and the source gas and the reactive gas are sequentially supplied has been known.

The vertical apparatus has a high throughput due to the great number of substrates to be processed at the same time, but it is difficult to ensure in-plane uniformity of the substrate. The single wafer apparatus can form a high quality film, but it is difficult to ensure the throughput when the substrates are processed one at a time. The rotary apparatus can form a film of higher quality than the vertical apparatus and has a higher throughput than the single wafer apparatus.

Also, in a thin film formation process, the substrate may not be processed at a high temperature due to a wire and the like formed on the substrate. In order to correspond to such problems, a method in which a gas is activated to plasma and the substrate is processed at a low temperature may be considered.

### RELATED ART DOCUMENT

### Patent Document

1. Japanese Laid-open Patent Application No. 2011-151294

2. Japanese Laid-open Patent Application No. 2010-206218

3. Japanese Laid-open Patent Application No. 2013-084898

### SUMMARY OF THE INVENTION

However, in the above rotary apparatus, since a center and an outer circumference of a substrate placement unit have different rotation speeds, it may be difficult to uniformly supply plasma into a surface of a substrate. In other words, since a density of plasma generated in a direction perpendicular to a rotation direction of the substrate placement unit is different, it may be difficult to uniformly supply plasma onto the substrate.

In view of the above-described problems, the present invention provides a configuration in which plasma can be uniformly supplied to the substrate in the rotary apparatus.

According to an aspect of the present invention, there is provided a configuration including: a process chamber including a source gas supply region and a reactive gas supply region and configured to process a plurality of substrates in the source gas supply region and the reactive gas supply region; a substrate placement unit capable of rotating in the process chamber, wherein the plurality of substrates are placed on the substrate placement unit along a rotational direction thereof; a plasma generating unit configured to generate plasma in plasma generation chamber installed at an upper portion of the reactive gas supply region; a coil wound along an outer circumference of the plasma generation chamber, wherein a portion of the coil adjacent to a sidewall of the plasma generation chamber has a constant curvature; a reactive gas supply system configured to supply a reactive gas to the reactive gas supply region via the plasma generation chamber through a ceiling of the plasma generation chamber, and a source gas supply system configured to supply a source gas to the source gas supply region.

### BRIEF DESCRIPTION OF THE DRAWINGS

FIG. 1 is a cross-sectional schematic view of a cluster type substrate processing apparatus according to a first embodiment of the present invention.

FIG. 2 is a vertical cross-sectional schematic view of the cluster type substrate processing apparatus according to the first embodiment of the present invention.

FIG. 3 is a cross-sectional schematic view of a process chamber included in the substrate processing apparatus according to the first embodiment of the present invention.

FIG. 4 is a vertical cross-sectional schematic view of the process chamber included in the substrate processing apparatus according to the first embodiment of the present invention and is a cross-sectional view of the process chamber taken along line A-A′ in FIG. 3.

FIG. 5 is a top schematic view of the process chamber included in the substrate processing apparatus according to the first embodiment of the present invention.

FIG. 6 is a diagram illustrating a plasma generating principle of a substrate processing apparatus according to an embodiment of the present invention.

FIG. 7 is a diagram illustrating a coil included in the substrate processing apparatus according to the first embodiment of the present invention.

FIG. 8 is a configuration diagram schematically illustrating a controller of a substrate processing apparatus that is preferably used in the first embodiment of the present invention.

FIG. 9 is a flowchart illustrating a substrate processing process according to the first embodiment of the present invention.

FIG. 10 is a flowchart illustrating a film formation process according to the first embodiment of the present invention.

FIG. 11 is a diagram illustrating a relation between a substrate and plasma in the substrate processing apparatus according to the first embodiment of the present invention.

FIG. 12 is a diagram illustrating a reactive gas according to the first embodiment of the present invention.

FIG. 13 is a diagram illustrating a Comparative Example of the present invention.

FIG. 14 is a diagram illustrating a comparison between the first embodiment of the present invention and the Comparative Example.

### DETAILED DESCRIPTION OF THE PREFERRED EMBODIMENTS

### First Embodiment of the Present Invention

Hereinafter, the first embodiment of the present invention will be described with reference to the drawings.

### (1) Configuration of Substrate Processing Apparatus

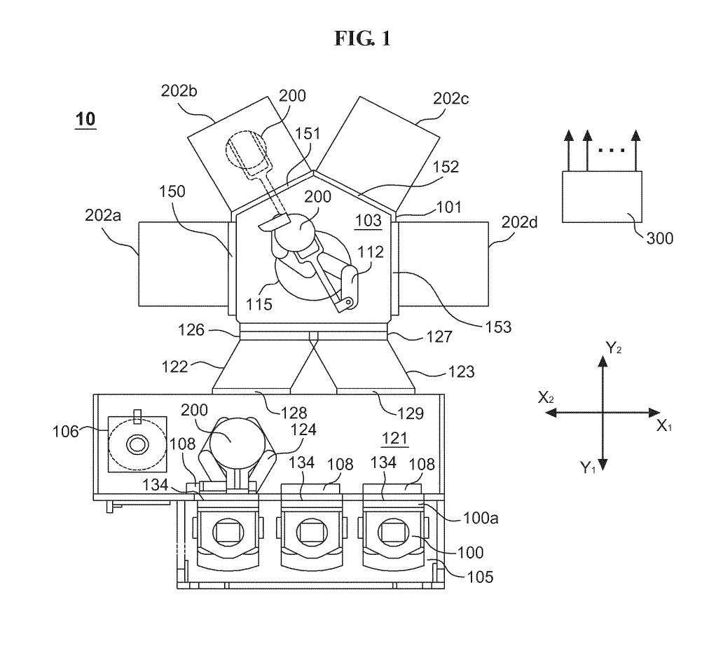

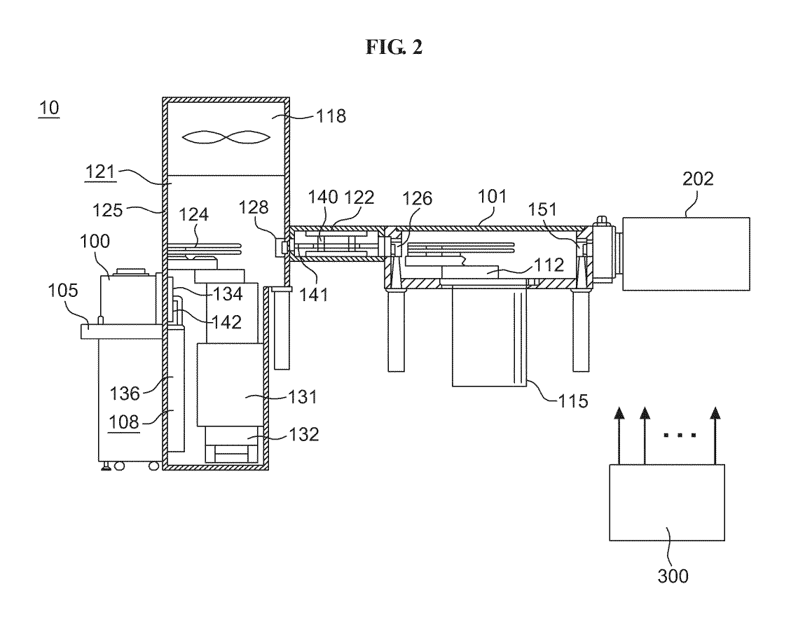

First, a substrate processing apparatus 10 according to the present embodiment will be described with reference to FIGS. 1 and 2.

Also, in the substrate processing apparatus 10 to which the present invention is applied, as a carrier for transferring a wafer 200 serving as a substrate, a front opening unified pod (FOUP) 100 (hereinafter referred to as a “pod”) is used. A transfer device of the cluster type substrate processing apparatus 10 according to the present embodiment is divided into a vacuum side and an atmosphere side.

Also, in the following description, front, rear, left and right are based on FIG. 1. A direction of X₁ is defined as the right, a direction of X₂ as the left, a direction of Y₁ as the front and a direction of Y₂ as the rear in FIG. 1.

[Configuration of Vacuum Side]

As illustrated in FIGS. 1 and 2, the substrate processing apparatus 10 includes a first transfer chamber 103 that can withstand a pressure (a negative pressure) below atmospheric pressure such as a vacuum state. A housing 101 of the first transfer chamber 103 has, for example, a pentagonal shape in a plan view and is formed to have a box shape whose upper and lower ends are closed. Also, the term “plan view” used below refers to a birds-eye view of the substrate processing apparatus 10.

A first wafer transfer device 112 capable of simultaneously transferring the two wafers 200 under a negative pressure is provided in the first transfer chamber 103. The first wafer transfer device 112 is configured to maintain airtightness of the first transfer chamber 103 and perform lifting by a first wafer transfer device elevator 115.

Among five sidewalls of the housing 101, at a sidewall located in a front side, spare chambers 122 and 123 (load lock chambers) are connected through gate valves 126 and 127, respectively. The spare chambers 122 and 123 are configured to have functions of both loading the wafer 200 and unloading the wafer 200 and are configured to have a structure that can withstand a negative pressure.

Also, the two wafers 200 may be placed to be stacked in the spare chambers 122 and 123 by a substrate support 140. A partitioning plate (intermediate plate) 141 disposed between the wafers 200 is provided in the spare chambers 122 and 123.

Among the five sidewalls of the housing 101 of the first transfer chamber 103, a first process chamber 202a, a second process chamber 202b, a third process chamber 202c and a fourth process chamber 202d, which perform a desired process on the substrate, are adjacently connected to four sidewalls located at a rear side (a back side) through gate valves 150, 151, 152 and 153, respectively. The process chambers (such as the first process chamber 202a) will be described below in detail.

[Configuration of Atmosphere Side]

A second transfer chamber 121 capable of transferring the wafer 200 under atmospheric pressure is connected to the front side of the spare chambers 122 and 123 through gate valves 128 and 129. A second wafer transfer device 124 configured to transfer the wafer 200 is provided in the second transfer chamber 121. The second wafer transfer device 124 is configured to be lifted by a second wafer transfer device elevator 131 provided in the second transfer chamber 121 and is configured to laterally reciprocate by a linear actuator 132.

A notch aligning device 106 is provided at a left side of the second transfer chamber 121. Also, the notch aligning device 106 may be an orientation flat aligning device. Also, a clean unit 118 configured to supply clean air is provided above the second transfer chamber 121.

At a front side of a housing 125 of the second transfer chamber 121, a substrate loading and unloading port 134 configured to load or unload the wafer 200 into or from the second transfer chamber 121 and a pod opener 108 are provided. At a side opposite to the pod opener 108, that is, at an outer side of the housing 125, a load port (IO stage) 105 is provided with the substrate loading and unloading port 134 therebetween. The pod opener 108 opens or closes a cap 100a of the pod 100 and includes a closure 142 capable of closing the substrate loading and unloading port 134 and a driving mechanism 136 configured to drive the closure 142. When the cap 100a of the pod 100 placed in the load port 105 is opened or closed, the wafer 200 may be loaded or unloaded into or from the pod 100. Also, the pod 100 is supplied or discharged to or from the load port 105 by an in-process transfer device (such as OHT) (not illustrated).

### (2) Configuration of Process Chamber

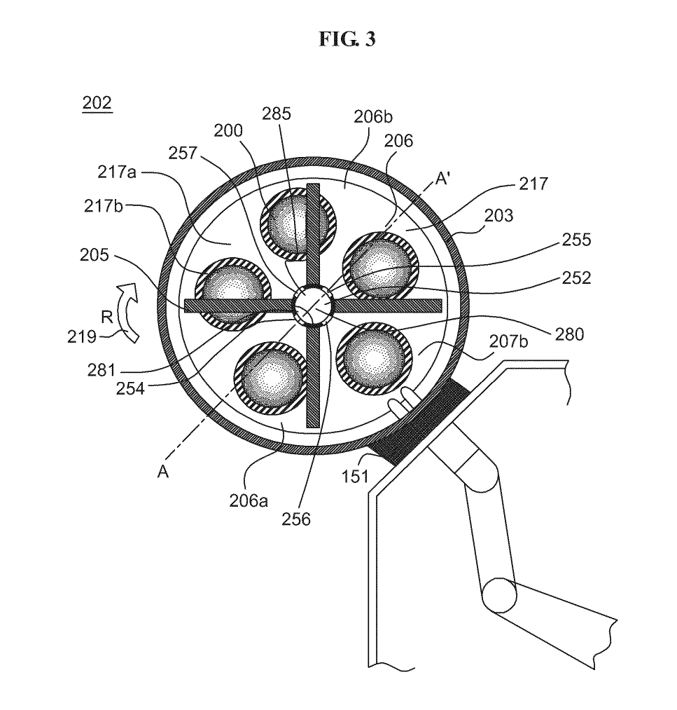

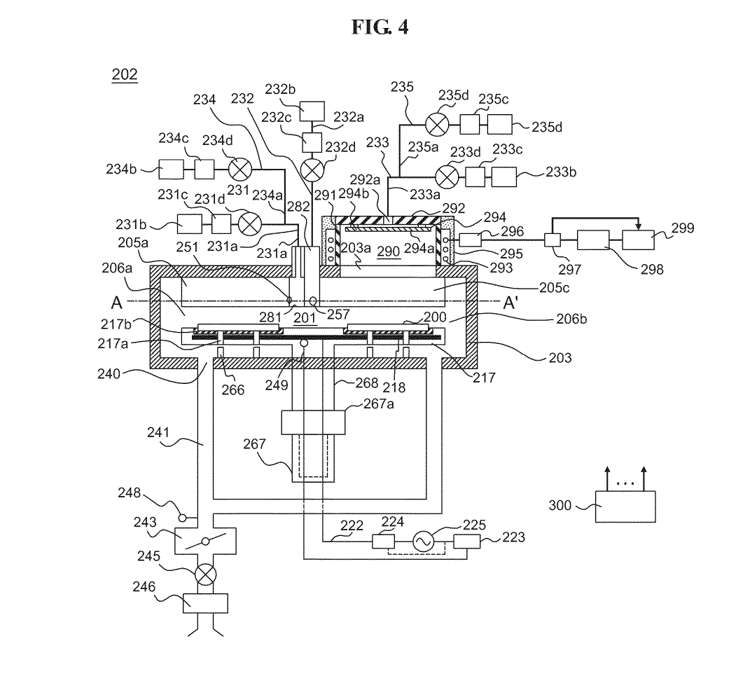

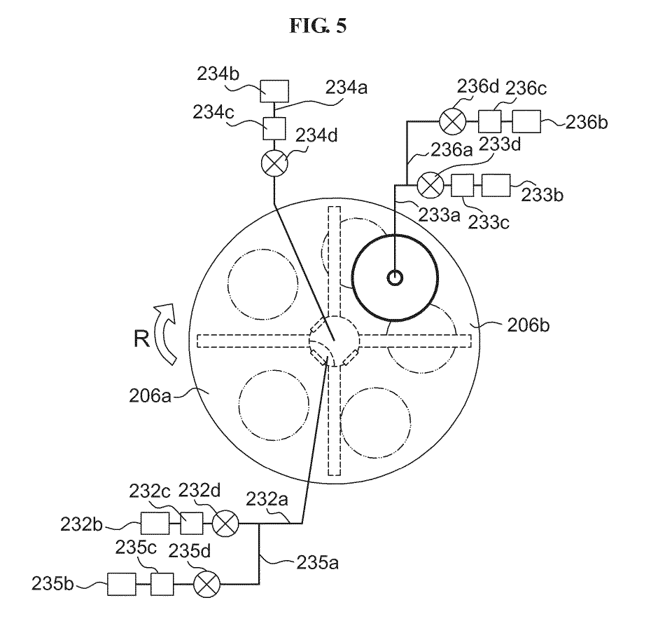

Next, a configuration of a process chamber serving as a processing furnace according to the present embodiment (the first embodiment) will be generally described with reference to FIGS. 3 to 5. Here, the line A-A′ illustrated in FIG. 4 is a line from A to A′ through the center of a reaction container 203.

Here, the first process chamber 202a, the second process chamber 202b, the third process chamber 202c and the fourth process chamber 202d of the present embodiment may have, for example, the same configuration. Hereinafter, the first process chamber 202a, the second process chamber 202b, the third process chamber 202c and the fourth process chamber 202d are collectively called a “process chamber 202.”

[Process Chamber]

As illustrated in FIGS. 3 and 4, the process chamber 202 serving as a processing furnace includes the reaction container 203 that is a cylindrical airtight container. A process chamber 201 configured to process the wafer 200 is formed in the reaction container 203.

The process chamber 201 is divided into a plurality of regions and includes, for example, a first processing region 206a, a first purge region 207a, a second processing region 206b and a second purge region 207b. As will be described below, a source gas is supplied into the first processing region 206a and plasma of a reactive gas is supplied into the second processing region 206b. Also, an inert gas is supplied to the first purge region 207a and the second purge region 207b. Therefore, a predetermined process is performed on the wafer 200 by the gas supplied into each of the regions.

Also, for example, four partition plates 205 that radially extend from a center portion are provided at an upper side in the reaction container 203. The four partition plates 205 are configured to divide the process chamber 201 into the first processing region 206a, the first purge region 207a, the second processing region 206b and the second purge region 207b while the wafer 200 passes through by rotation of a susceptor 217 to be described below. Specifically, the process chamber 201 includes a gap under the plurality of partition plates 205 where the wafer 200 passes through. The plurality of partition plates 205 are provided to block a space immediately above the susceptor 217 from a ceiling portion in the process chamber 201. A lower end of the partition plate 205 is disposed adjacent to the susceptor 217 to an extent that the partition plate 205 does not interfere with the wafer 200. Accordingly, an amount of a gas that passes between the partition plate 205 and the susceptor 217 decreases and thus mixing of the gases between regions in the process chamber 201 is suppressed.

Also, a gap of a predetermined width is provided between an end of the partition plate 205 in a horizontal direction and a sidewall of the reaction container 203 such that a gas passes through. The inert gas is ejected from insides of the first purge region 207a and the second purge region 207b into the first processing region 206a and the second processing region 206b with the gap therebetween. Accordingly, it is possible to suppress a processing gas such as a first gas and a second gas from being introduced into the first purge region 207a and the second purge region 207b and it is possible to suppress a reaction of the processing gas in the first purge region 207a and the second purge region 207b.

Here, a time taken for the predetermined wafer 200 to pass through the first processing region 206a, the first purge region 207a, the second processing region 206b and the second purge region 207b, that is, a processing time taken for the wafer 200 at each of the regions depends on an area (volume) of each of the regions when the susceptor 217 to be described below has a constant rotation speed. Also, when the susceptor 217 to be described below has a constant rotation speed, the processing time of the wafer 200 at each of the regions depends on each area of the first processing region 206a, the first purge region 207a, the second processing region 206b and the second purge region 207b in a plan view. In other words, the processing time of the wafer 200 at each of the regions depends on an angle of the adjacent partition plate 205.

[Susceptor]

At a lower side of the partition plate 205, that is, at a bottom center in the reaction container 203, for example, the susceptor 217 that has an axis of rotation at the center of the reaction container 203 and serves as a substrate placement unit that is rotatable is provided. The susceptor 217 is made of, for example, carbon or SiC in order to decrease metal contamination of the wafer 200. Also, the susceptor 217 and the reaction container 203 are electrically insulated.

The susceptor 217 is configured to arrange and support the plurality (five) of wafers 200 on the same plane and on the same circumference in a rotation direction in the reaction container 203. Here, the term “the same plane” is not limited to exactly the same plane, but merely indicates that the plurality of wafers 200 are arranged not to be stacked when the susceptor 217 is seen from the top.

A wafer placement portion 217b is provided at a support position of the wafer 200 on a surface of the susceptor 217. The same number of the wafer placement portions 217b as the number of wafers 200 to be processed are concentrically disposed at equal intervals from the center of the susceptor 217 (for example, an interval of 72°). Also, in the present embodiment, an angle of the partition plate 205 is determined by each of the regions that have the same area (volume). However, this is only an example and it is needless to say that the angle of the partition plate 205 may be arbitrarily determined.

Each of the wafer placement portions 217b has, for example, a circular shape when seen from the top of the susceptor 217 and has a concave shape when seen from the side. Preferably, the wafer placement portion 217b has a diameter that is slightly increased than a diameter of the wafer 200. When the wafer 200 is placed in the wafer placement portion 217b, a position of the wafer 200 may be easily determined. Also, it is possible to suppress a position deviation of the wafer 200 such as the wafer 200 protruding from the susceptor 217 due to centrifugal force resulting from rotation of the susceptor 217.

A lifting mechanism 268 configured to lift the susceptor 217 is provided in the susceptor 217. A plurality of through holes 217a are provided in a position of each of the wafer placement portions 217b of the susceptor 217. At a bottom surface of the above-described reaction container 203, a plurality of wafer lift pins 266 configured to lift the wafer 200 and support a rear surface of the wafer 200 when the wafer 200 is loaded or unloaded into or from the reaction container 203 are provided. The through hole 217a and the wafer lift pin 266 are disposed such that the wafer lift pin 266 passes through the through hole 217a in non-contact with the susceptor 217 when the wafer lift pin 266 is raised or when the susceptor 217 is lowered by the lifting mechanism 268.

In the lifting mechanism 268, a rotating mechanism 267 configured to rotate the susceptor 217 such that the plurality of wafers 200 sequentially pass through the first processing region 206a, the first purge region 207a, the second processing region 206b and the second purge region 207b is provided. The rotating mechanism 267 has an axis of rotation (not illustrated) that is connected to the susceptor 217 and is configured to rotate the five wafer placement portions 217b in a collective manner by rotating the susceptor 217.

Also, a controller 300 to be described below is connected to the rotating mechanism 267 through a coupling portion 267a. The coupling portion 267a is configured as, for example, a slip ring mechanism configured to electrically connect between a rotation side and a fixed side by a metal brush and the like. Accordingly, rotation of the susceptor 217 is not interfered.

[Heating Unit]

A heater 218 serving as a heating unit is integrally embedded in the susceptor 217 in order to heat the wafer 200. The heater 218 is configured to heat a surface of the wafer 200 to a predetermined temperature (for example, room temperature to 1,000° C.). Also, the heater 218 may be configured to individually heat each of the wafers 200 that are placed in the susceptor 217.

A temperature sensor 249 is provided in the susceptor 217. A power regulator 224, a heater power source 225 and a temperature regulator 223 are electrically connected to the heater 218 and the temperature sensor 249 through a power supply line 222. The heating unit includes the heater 218, the temperature sensor 249, the power supply line 222, the power regulator 224, the heater power source 225 and the temperature regulator 223.

[Source Gas Supply System]

A first gas inlet 281 is provided at a center portion of a ceiling portion of the reaction container 203. A downstream end of a first gas supply pipe 231a is connected to an upper end of the first gas inlet 281. A first gas outlet 251 that is open to the first processing region 206a is provided at a sidewall of the first processing region 206a side of the first gas inlet 281.

In the first gas supply pipe 231a, in order from an upstream end, a source gas supply source 231b, a mass flow controller (MFC) 231c serving as a flow rate controller (flow rate control unit) and a valve 231d serving as an on-off valve are provided.

Through the first gas supply pipe 231a, the source gas is supplied into the first processing region 206a with the MFC 231c, the valve 231d, the first gas inlet 281 and the first gas outlet 251 therebetween.

Also, a downstream end of an inert gas supply pipe 234a is connected to a downstream side from the valve 231d of the first gas supply pipe 231a. In the inert gas supply pipe 234a, in order from an upstream end, an inert gas supply source 234b, an MFC 234c and a valve 234d are provided. Through the inert gas supply pipe 234a, the inert gas is supplied into the first processing region 206a with the MFC 234c, the valve 234d, the first gas supply pipe 231a, the first gas inlet 281 and the first gas outlet 251 therebetween. The inert gas supplied into the first processing region 206a serves as a carrier gas or a dilution gas of the source gas.

Here, the term “source gas” is one of the processing gases and is a gas that serves as a source when a thin film is formed. For example, the source gas includes, for example, at least one of titanium (Ti), tantalum (Ta), silicon (Si), hafnium (Hf), zirconium (Zr), ruthenium (Ru), nickel (Ni) and tungsten (W) as an element that forms the thin film.

In the present embodiment, a halosilane source gas containing silicon (Si) and a halogen element is used. Here, the halosilane source gas refers to a halosilane source in a gas state, for example, a gas that is obtained by vaporizing a halosilane source in a liquid state under room temperature and room pressure, a halosilane source in a gas state under room temperature and room pressure and the like. The halosilane source is a silane source containing a halogen group. The halogen element includes at least one selected from the group consisting of chlorine (Cl), fluorine (F), bromine (Br) and iodine (I).

As the halosilane source gas, for example, a source gas containing Si and Cl, that is, a chlorosilane source gas may be used. As the chlorosilane source gas, for example, dichlorosilane (Si₂H₂Cl₂, abbreviated to: DCS) gas may be used.

Specifically, in the present embodiment, the source gas is, for example, DCS gas. When a material of the source gas is a gas at room temperature, the MFC 231c is a mass flow controller for a gas. Also, when the material of the source gas is a liquid at room temperature, the MFC 231c is a mass flow controller for a liquid. A vaporizer is provided between the MFC 231c and the valve 231d. Also, in a bubbling method, the MFC 231c is a mass flow controller for a carrier gas and is connected to an upstream of the source gas supply source 231b.

A source gas supply system (may also be called a first gas supply system or a source gas supply unit) mainly includes the first gas supply pipe 231a, the MFC 231c, the valve 231d, the first gas inlet 281 and the first gas outlet 251. Also, the source gas supply source 231b may be included in the source gas supply system.

Also, the inert gas supply pipe 234a, the MFC 234c and the valve 234d may be included in the source gas supply system.

[Inert Gas Supply System]

An inert gas inlet 282 is provided at a center portion of the ceiling portion of the reaction container 203. At sidewalls of the first purge region 207a side and the second purge region 207b side of the inert gas inlet 282, a first inert gas outlet 256 that is open to the first purge region 207a and a second inert gas outlet 257 that is open to the second purge region 207b are provided, respectively.

A downstream end of a second gas supply pipe 232a is connected to an upper end of the inert gas inlet 282. In the second gas supply pipe 232a, in order from an upstream end, an inert gas supply source 232b, an MFC 232c and a valve 232d are provided. Through the second gas supply pipe 232a, the inert gas is supplied into the first purge region 207a and the second purge region 207b with the MFC 232c, the valve 232d, the inert gas inlet 282, the first inert gas outlet 256 and the second inert gas outlet 257 therebetween. The inert gas supplied into the first purge region 207a and the second purge region 207b serves as a purge gas.

An inert gas supply system mainly includes the second gas supply pipe 232a, the MFC 232c, the valve 232d, the inert gas inlet 282, the inert gas outlet 256 and the inert gas outlet 257. Also, the inert gas supply source 232b may be included in the inert gas supply system (is also called an inert gas supply unit).

Here, the term “inert gas” refers to, for example, at least one of rare gases such as nitrogen (N₂) gas, helium (He) gas, neon (Ne) gas and argon (Ar) gas. Here, the inert gas is, for example, N₂ gas.

[Reactive Gas Supply System]

In the ceiling portion of the reaction container 203, a communication port 203a is provided above the second processing region 206b. A plasma generating chamber 290 to be described below is connected to the communication port 203a. A reactive gas inlet hole 292a is provided at a ceiling 292 of the plasma generating chamber 290. A reactive gas supply system 233 (is also called a reactive gas supply unit) is connected to the reactive gas inlet hole 292a.

A downstream end of a third gas supply pipe 233a is connected to the reactive gas inlet hole 292a. In the third gas supply pipe 233a, in order from an upstream end, a reactive gas supply source 233b, a mass flow controller (MFC) 233c serving as a flow rate controller (flow rate control unit) and a valve 233d serving as an on-off valve are provided.

As a reactant that contains an element (second to fourth elements) other than the above-described Si element, for example, a nitrogen (N)-containing gas serving as the reactive gas is supplied into the second processing region 206b from the reactive gas supply source 233b through the MFC 233c, the valve 233d, the plasma generating chamber 290 and the communication port 203a. As the N-containing gas, for example, a nitride hydrogen-based gas may be used. The nitride hydrogen-based gas may be a material that consists of only two elements N and H and serves as a nitriding gas, that is, an N source in a substrate processing process to be described below. As the nitride hydrogen-based gas, for example, ammonia (NH₃) gas may be used.

Also, a downstream end of an inert gas supply pipe 235a is connected to a downstream side from the valve 233d of the third gas supply pipe 233a. In the inert gas supply pipe 235a, in order from an upstream end, an inert gas supply source 235b, an MFC 235c and a valve 235d are provided. Through the inert gas supply pipe 235a, the inert gas is supplied into a third processing region 206c with the MFC 235c, the valve 235d, the third gas supply pipe 233a, the plasma generating chamber 290 and the communication port 203a therebetween. The inert gas supplied into the third processing region 206c serves as a carrier gas or a dilution gas, similar to the inert gas supplied into the first processing region 206a.

Here, the term “reactive gas” is one of the processing gases and is a gas that becomes a plasma state and reacts with a first layer that is formed on the wafer 200 by the source gas as will be described below. The reactive gas is, for example, at least one of NH₃ gas, nitrogen (N₂) gas, hydrogen (H₂) gas and oxygen (O₂) gas or combinations thereof. Also, the reactive gas uses a material having a lower degree of tackiness (viscosity) than the source gas. In the present embodiment, the reactive gas is NH₃ gas.

A reactive gas supply unit (second gas supply unit) mainly includes the third gas supply pipe 233a, the MFC 233c, the valve 233d and the reactive gas inlet hole 292a. Also, the reactive gas supply source 233b may be included in the reactive gas supply system.

Also, the inert gas supply pipe 235a, the MFC 235c and the valve 235d may be included in the reactive gas supply system.

[Exhaust System]

As illustrated in FIG. 4, an exhaust port 240 configured to exhaust an inside of the reaction container 203 is provided at a bottom of the reaction container 203. For example, a plurality of exhaust ports 240 are provided at bottoms of the first processing region 206a, the first purge region 207a, the second processing region 206b and the second purge region 207b, respectively.

An upstream end of an exhaust pipe 241 is connected to each of the exhaust ports 240. For example, the exhaust pipes 241 connected to each of the exhaust ports 240 converge into one at a downstream side. A vacuum pump 246 serving as a vacuum exhaust device is connected to a downstream side from a part at which the exhaust pipes 241 converge through a pressure sensor 248, an auto pressure controller (APC) valve 243 serving as a pressure regulator (pressure regulating unit) and a valve 245 serving as an on-off valve and is configured to vacuum exhaust such that a pressure in the process chamber 201 becomes a predetermined pressure (a degree of vacuum). The APC valve 243 is an on-off valve that may perform vacuum exhaust or vacuum exhaust stop in the process chamber 201 by opening or closing the valve and regulate a pressure in the process chamber 201 by adjusting a degree of valve opening. An exhaust system mainly includes the exhaust pipe 241, the APC valve 243 and the valve 245. Also, the exhaust system (is also called an exhaust part) may include the pressure sensor 248 and the vacuum pump 246.

[Plasma Generating Unit]

The communication port 203a having a greater diameter than that of the substrate (for example, the wafer 200) is provided at a ceiling portion in the second processing region 206b of the reaction container 203. The plasma generating chamber 290 is connected to the communication port 203a. The plasma generating chamber 290 includes a sidewall 291 and the ceiling 292 and is connected to the reactive gas supply system through the reactive gas inlet hole 292a provided at the ceiling 292. The sidewall 291 has a structure of a cylindrical shape and has an outer circumference on which a coil 293 is wound. The sidewall 291 is made of, for example, quartz and has a greater diameter than that of the substrate. The sidewall 291 has the same diameter as that of the communication port 203a. The communication port 203a is disposed at a position in which an outer circumference of the wafer 200 passes through an inside of the communication port 203a.

In the direction of gravity, a gas dispersion structure 294 is provided between the reactive gas inlet hole 292a provided at the ceiling 292 and an upper end of the coil 293. The gas dispersion structure 294 includes a gas dispersion plate 294a and a fixing structure 294b for fixing the plate at the ceiling. The gas dispersion plate 294a is a circular plate having no hole and has a member in a diameter direction that extends in a direction of the coil 293 such that a gas supplied through the reactive gas inlet hole 292a is guided to the vicinity of the coil 293. The fixing structure 294b includes a plurality of posts and has a structure in which a flow of a gas supplied through the gas inlet hole 292a is not interfered. One end of the fixing structure 294b is fixed to a part of the gas dispersion plate 294a and the other end thereof is fixed to the ceiling 292.

As described above, the upper end of the coil 293 in the direction of gravity is positioned below the gas dispersion plate 294a. The coil 293 is surrounded by a shielding plate 295. The shielding plate 295 blocks an electromagnetic wave and the like generated from the coil 293.

As illustrated in FIG. 6, a part forming a circumference of the coil 293, that is, a part adjacent to the sidewall 291 has a curvature of a constant shape. By the constant curvature, a magnetic field generated when a current flows in the coil is uniformized along an inner circumference of the sidewall 291 and thus a density in a circumferential direction of generated plasma 290a may be uniformized.

A waveform adjusting circuit 296, an RF sensor 297, a high frequency power source 298 and a frequency matching unit 299 are connected to the coil 293 as a power supply unit.

The high frequency power source 298 supplies high frequency power to the coil 293. The RF sensor 297 is provided to an output side of the high frequency power source 298. The RF sensor 297 monitors information on a supplied high frequency traveling wave or a reflected wave. The frequency matching unit 299 controls the high frequency power source 298 so that the reflected wave is minimized based on the information on the reflected wave monitored by the RF sensor 297.

In order to form a standing wave of a predetermined wavelength, a winding diameter, a winding pitch and the number of windings of the coil 293 are set to resonate in a constant wavelength mode. That is, a combined electrical length of the coil 293 and the adjacent waveform adjusting circuit 296 (to be described below in detail) is set to a length that corresponds to an integer multiple (once, twice, . . . ) of one wavelength at a predetermined frequency of power supplied from the high frequency power source 298. For example, a length of one wavelength is about 22 m in 13.56 MHz, a length of one wavelength is about 11 m in 27.12 MHz and a length of one wavelength is about 5.5 m in 54.24 MHz.

Both ends of the coil 293 are electrically grounded, but at least one end of the coil 293 is grounded through a moveable tap in order to finely regulate the electrical length of the resonant coil when the device is initially provided or a process condition is changed. The other end of the coil 293 is connected to fixed ground. Also, when the device is initially provided or the process condition is changed, the power supply unit is configured by the moveable tap between the grounded both ends of the coil 293 in order to finely regulate an impedance of the coil 293.

That is, the coil 293 includes ground portions that are electrically grounded at both ends and includes the power supply unit whose power is supplied from the high frequency power source 298 between the ground portions. Also, at least one ground portion is a position adjustable variable ground portion and the power supply unit is a position adjustable variable power supply unit. When the coil 293 includes the variable ground portion and the variable power supply unit, a resonance frequency and a load impedance of the process chamber 201 can be regulated more easily as will be described below. A plasma generating principle will be described below.

The shielding plate 295 is provided to shield a leakage of the electromagnetic wave to the outside of the coil 293 and form a capacity component necessary for forming a resonant circuit with the coil 293 therebetween. The shielding plate 295 generally uses a conductive material such as an aluminum alloy, copper, or a copper alloy and is formed to have a cylindrical shape. The shielding plate 295 is separated, for example, about 5 mm to 150 mm, from an outer circumference of the coil 293.

The RF sensor 297 is provided at an output side of the high frequency power source 298 and monitors a traveling wave towards the coil 293, a reflected wave reflected from the coil 293 and the like. The reflected wave power monitored by the RF sensor 297 is input to the frequency matching unit 299. The frequency matching unit 299 controls a frequency so that the reflected wave is minimized.

The plasma generating unit according to the present embodiment mainly includes the plasma generating chamber 290, the coil 293, the waveform adjusting circuit 296, the RF sensor 297 and the frequency matching unit 299. Also, the high frequency power source 298 may be included in plasma generating unit.

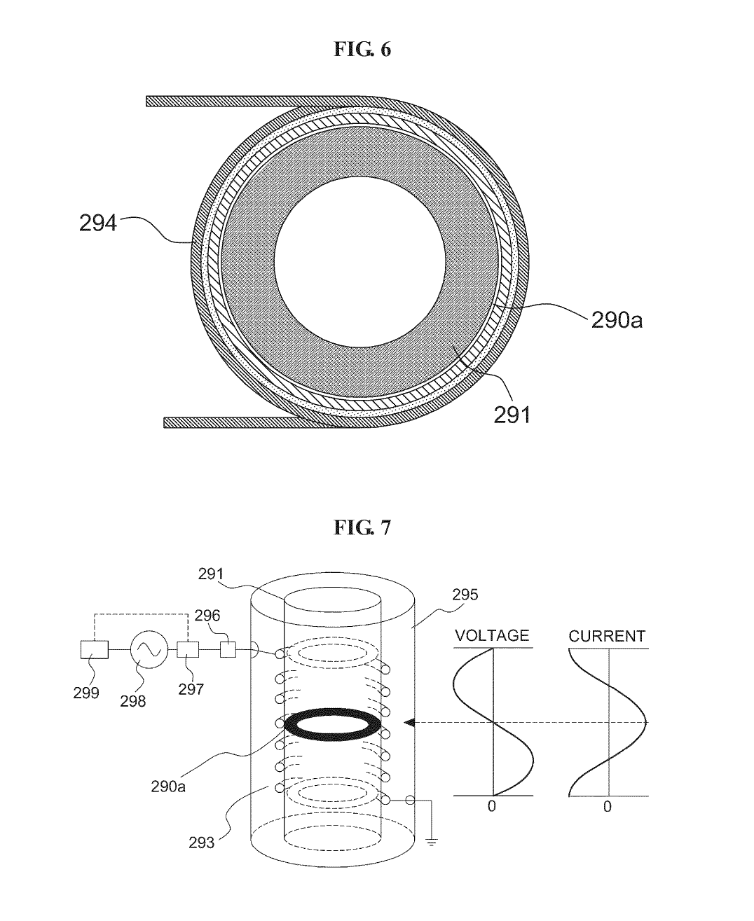

Here, the plasma generating principle of the apparatus according to the present embodiment and properties of generated plasma will be described with reference to FIG. 7.

In order to form a standing wave of a predetermined wavelength, a winding diameter, a winding pitch, and the number of windings of the coil 293 are set to resonate in an entire wavelength mode. That is, a combined electrical length of the coil 293 and the waveform adjusting circuit 296 is set to a length that corresponds to an integer multiple (once, twice, . . . ) of one wavelength at a predetermined frequency of power supplied from the high frequency power source 298.

Specifically, in consideration of power to be applied, a magnetic field strength to be generated, an external shape of an apparatus to be applied and the like, the coil 293 has an effective cross-sectional area of 50 mm² to 300 mm² and a coil diameter of 200 mm to 500 mm such that a magnetic field of about 0.01 Gauss to 10 Gauss can be generated by high frequency power of, for example, 800 kHz to 50 MHz, 0.5 KW to 5 KW and is wound on an outer circumference side of a part that forms the sidewall 291 twice to 60 times. Also, as a material of the coil 293, a copper pipe, a thin copper plate, an aluminum pipe, a thin aluminum plate, a material in which copper or aluminum is deposited on a polymer belt or the like is used.

Also, in order to finely regulate the electrical length of the resonant coil and set a resonance characteristic to be substantially the same as that of the high frequency power source 298, one end or both ends of the coil 293 are generally grounded through the moveable tap. Also, the waveform adjusting circuit 296 is inserted into one end (or the other end or both ends) of the coil 293 such that phase and reverse phase currents symmetrically flow with respect to an electrical midpoint of the coil 293. The waveform adjusting circuit is configured as an open circuit by setting an end of the coil 293 to an electrically unconnected state or an electrically equivalent state. Also, the end of the coil 293 may be non-grounded by a choke series resistance and be DC connected to a fixed reference potential.

The shielding plate 295 is provided to shield an electric field of the outside of the coil 293 and form a capacity component (C component) necessary for forming the resonant circuit with the coils 293 therebetween. The shielding plate 295 generally uses a conductive material such as an aluminum alloy, copper, or a copper alloy and is formed to have a cylindrical shape. The shielding plate 295 is separated about 5 mm to 150 mm from the outer circumference of the coil 293. Also, typically, the shielding plate 295 is grounded to have the same potential as both ends of the coil 293. However, in order to set the number of resonances of the coil 293 accurately, one end or both ends of the shielding plate 295 may regulate a tap position. Also, in order to set the number of resonances accurately, a trimming capacitance may be inserted between the coil 293 and the shielding plate 295.

The high frequency power source 298 includes a power control device (control circuit) having a preamp and a high frequency oscillation circuit configured to define an oscillation frequency and an output and an amplifier (output circuit) configured to perform amplification to a predetermined output. The power control device controls the amplifier based on preset frequency and power output conditions through an operation panel. The amplifier supplies constant high frequency power to the coil 293 through a transmission line.

Also, a plasma generating circuit formed of the coil 293 is an RLC parallel resonant circuit. When a wavelength of the high frequency power source 298 and an electrical length of the coil 293 are the same, a resonance condition of the coil 293 is satisfied when a reactance component generated by a capacity component or an inductance component of the coil 293 is offset and becomes a pure resistance. However, when the plasma generating circuit generates plasma, an actual resonance frequency is slightly changed by capacitive coupling between plasma and a voltage part of the coil 293, changes in plasma in plasma generating chamber 290, or an excited state of plasma.

Accordingly, in the present embodiment, in order for a power source side to compensate for a deviation of resonance at the coil 293 when plasma is generated, the frequency matching unit 299 has a function of detecting reflected wave power from the coil 293 when plasma is generated and compensating for an output. In such a configuration, in a resonance device of the present invention, a standing wave may be formed at the coil 293 more accurately. Therefore, it is possible to generate plasma having extremely low capacitive coupling.

That is, the frequency matching unit 299 detects reflected wave power from the coil 293 when plasma is generated and increases or decreases the predetermined frequency such that the reflected wave power is minimized. Specifically, the frequency matching unit 299 includes a frequency control circuit configured to correct a preset oscillation frequency. Also, at an output side of the amplifier, a reflected wave power meter is provided as a part of the frequency matching unit 299 that detects reflected wave power in a transmission line and feeds a voltage signal thereof back to the frequency control circuit.

The frequency control circuit includes an A/D converter configured to receive a voltage signal from the reflected wave power meter and perform digital conversion of the voltage signal into a frequency signal, an arithmetic processing circuit configured to perform addition and subtraction processing of a value of a frequency signal that corresponds to the converted reflected wave and a value of an oscillation frequency that is preset and stored, an D/A converter configured to perform analog conversion of the frequency value obtained by addition and subtraction processing into a voltage signal and a voltage controlled oscillator configured to perform oscillation according to an applied voltage from the D/A converter. Therefore, the frequency control circuit oscillates at a no-load resonance frequency of the coil 293 before plasma lighting and oscillates at a frequency that is increased or decreased from the predetermined frequency such that reflected power is minimized after plasma lighting. As a result, the frequency signal is transmitted to the amplifier such that there is no reflected wave in the transmission line.

In the present embodiment, a pressure in plasma generating chamber 290 is decreased to, for example, 0.01 Torr to 50 Torr and then a plasma gas (a nitrogen-containing gas in the present embodiment) is supplied to the plasma generating chamber 290 while maintaining the degree of vacuum. Also, when high frequency power of, for example, 27.12 MHz, 2 KW, is supplied to the coil 293 from the high frequency power source 298, an induced electric field is generated in plasma generating chamber 290. As a result, the supplied gas becomes a plasma state in plasma generating chamber 290.

The frequency matching unit 299 provided in the high frequency power source 298 compensates for a deviation of a resonance point of the coil 293 due to changes in capacitive coupling or inductive coupling of the generated plasma at the high frequency power source 298 side. That is, the RF sensor 297 of the frequency matching unit 299 detects reflected wave power according to changes in capacitive coupling or inductive coupling of plasma, decreases or increases the predetermined frequency by an extent that corresponds to a deviation of the resonance frequency causing reflected wave power such that reflected wave power is minimized and outputs a high frequency of the resonance frequency of the coil 293 to the amplifier under a plasma condition.

In other words, in the resonance device of the present invention, when plasma is generated and a plasma generating condition is changed, in order to output a high frequency of a frequency that accurately resonates according to a deviation of the resonance point of the coil 293, a standing wave can be formed in the coil 293 more accurately. That is, as illustrated in FIG. 7, in the coil 293, according to transmission of an actual resonance frequency of the resonator including plasma, a standing wave in which a phase voltage and an reverse phase voltage are constantly offset is formed and the highest phase current is generated at an electrical midpoint (a node having zero voltage) of the coil. Therefore, induction plasma excited at the electrical midpoint has almost no capacitive coupling with a process chamber wall or the substrate placement unit. In plasma generating chamber 290, the plasma 290a having an extremely low electric potential, a ring shape and a uniform density in a circumferential direction may be formed.

[Control Unit]

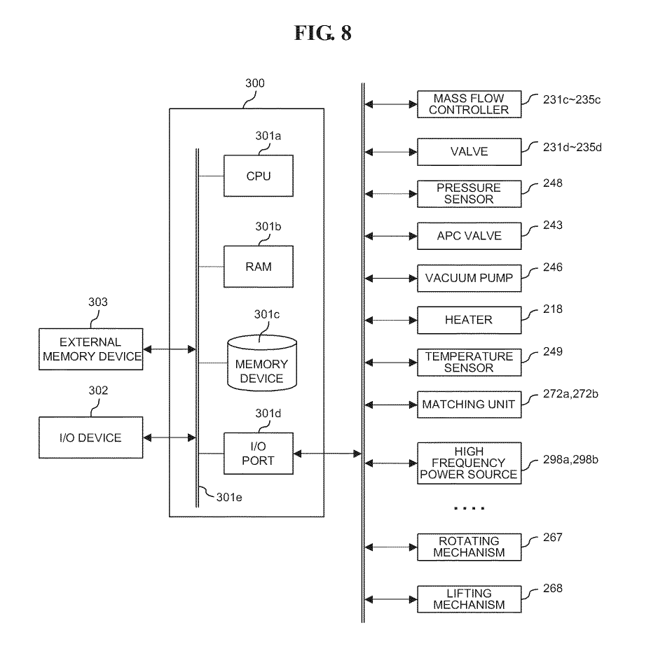

Next, the controller 300 serving as a control unit (control device) of the present embodiment will be described with reference to FIG. 8.

As illustrated in FIG. 8, the controller 300 serving as a control unit (control device) is configured as a computer that includes a central processing unit (CPU) 301a, a random access memory (RAM) 301b, a memory device 301c and an I/O port 301d. The RAM 301b, the memory device 301c and the I/O port 301d are configured to exchange data with the CPU 301a through an internal bus 301e. An I/O device 302 configured as, for example, a touch panel, is connected to the controller 300.

The memory device 301c is configured as, for example, a flash memory, a hard disk drive (HDD) or the like. A control program controlling operations of the substrate processing apparatus 10 or a process recipe describing sequences or conditions of substrate processing such as a film formation process to be described below are readably stored in the memory device 301c. Also, the process recipe, which is a combination of sequences, causes the controller 300 to execute each sequence in a substrate processing process to be described below in order to obtain a predetermined result and functions as a program. Hereinafter, such a process recipe, a control program and the like are collectively simply called a “program.” Also, when the term “program” is used in this specification, it may refer to either or both of the process recipe and the control program. Also, the RAM 301b is configured as a memory area (work area) in which a program, data and the like read by the CPU 301a are temporarily stored.

The I/O port 301d is connected to the MFCs 231c, 232c, 233c, 234c and 235c, the valves 231d, 232d, 233d, 234d and 235d, the pressure sensor 248, the APC valve 243, the vacuum pump 246, the heater 218, the temperature sensor 249, a high frequency power source 298a and a matching unit 272a of a reactive gas plasma generating unit 270a, a high frequency power source 298b and a matching unit 272b of a modifying gas plasma generating unit 270b, the rotating mechanism 267, the lifting mechanism 268 and the like. Also, the I/O port 301d is connected to the power regulator 224, the heater power source 225 and the temperature regulator 223 which are not illustrated.

The CPU 301a reads and executes the control program from the memory device 301c and reads the process recipe from the memory device 301c according to an input of a manipulating command from the I/O device 302. Also, to comply with the contents of the read process recipe, the CPU 301a is configured to control a flow rate regulating operation of various gases by the MFCs 231c, 232c, 233c, 234c and 235c, an opening or closing operation of the valves 231d, 232d, 233d, 234d and 235d, an opening or closing operation of the APC valve 243, a pressure regulating operation by the APC valve 243 based on the pressure sensor 248, a temperature regulating operation by the heater 218 based on the temperature sensor 249, starting and stopping of the vacuum pump 246, a rotation and rotation speed adjusting operation of the susceptor 217 by the rotating mechanism 267, a lifting operation of the susceptor 217 by the lifting mechanism 268, power supply and stop by the high frequency power source 298a and the like.

Also, the controller 300 is not limited to being configured as a dedicated computer, but may be configured as a general-purpose computer. For example, the controller 300 according to the present embodiment may be configured by preparing an external memory device 303 (for example, a magnetic tape, a magnetic disk such as a flexible disk and a hard disk, an optical disc such as a CD or a DVD, a magneto-optical disc such as an MO and a semiconductor memory such as a USB memory and a memory card) recording the above-described program and then installing the program in the general-purpose computer using the external memory device 303. Also, a method of supplying the program to the computer is not limited to supplying through the external memory device 303. For example, a communication line such as the Internet or an exclusive line may be used to supply the program without the external memory device 303. Also, the memory device 301c or the external memory device 303 is configured as a non-transitory computer-readable recording medium. Hereinafter, these are also collectively simply called a recording medium. Also, when the term “recording medium” is used in this specification, it refers to either or both of the memory device 301c and the external memory device 303.

### (3) Substrate Processing Process

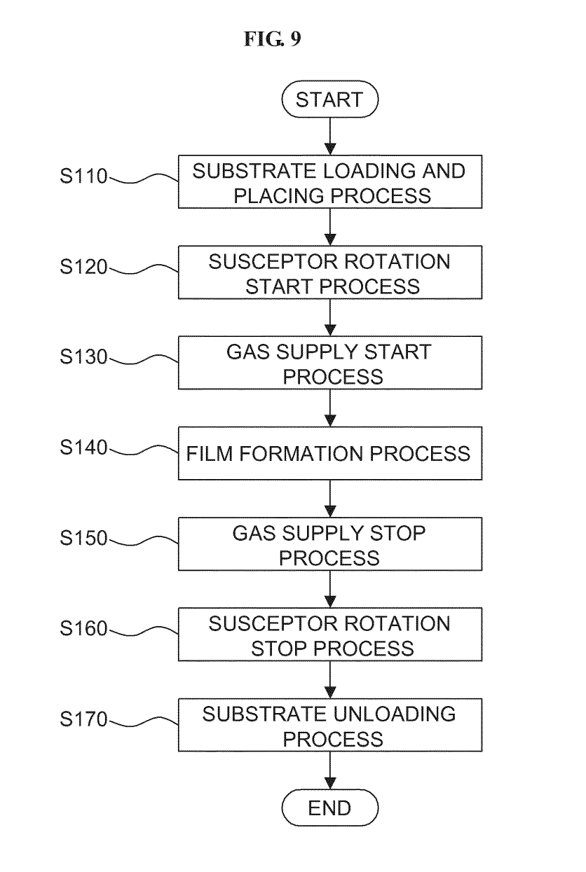

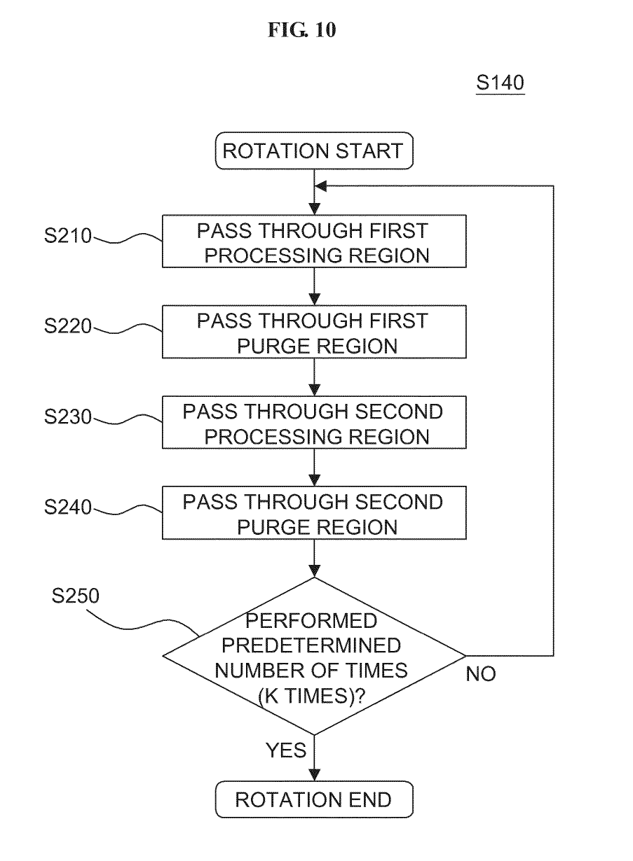

Next, a substrate processing process according to the first embodiment will be described with reference to FIGS. 9 and 10.

Here, an example in which DCS gas is used as the source gas and NH₃ gas is used as the reactive gas to form a silicon nitride (SiN) film on the wafer 200 as a thin film will be described. Also, in the wafer 200 on which an SiN film is formed, for example, a step portion in which a semiconductor device is processed is formed.

[Substrate Loading and Placing Process (S110)]

For example, the pod 100 in which a maximum of 25 wafers 200 are accommodated is transferred by an in-process transfer device and placed on the load port 105. The cap 100a of the pod 100 is removed by the pod opener 108 and a loading and unloading opening of the substrate of the pod 100 is opened. The second wafer transfer device 124 picks up the wafer 200 from the pod 100 to place on the notch aligning device 106. The notch aligning device 106 regulates a position of the wafer 200. The second wafer transfer device 124 loads the wafer 200 into the spare chamber 122 in an atmospheric pressure state from the notch aligning device 106. The gate valve 128 is closed and an inside of the spare chamber 122 is exhausted at a negative pressure by an exhaust device (not illustrated).

In the process chamber 202, when the susceptor 217 is lowered to a transfer position of the wafer 200, the wafer lift pin 266 penetrates the through hole 217a of the susceptor 217. As a result, the wafer lift pin 266 protrudes from the surface of the susceptor 217 by a predetermined height. Subsequently, a predetermined gate valve is opened and a predetermined number (for example, five) of wafers 200 (substrates to be processed) are loaded into the process chamber 201 using the first wafer transfer device 112. Then, around an axis of rotation (not illustrated) of the susceptor 217, the wafers 200 are placed not to be stacked in a rotation direction of the susceptor 217. Accordingly, the wafer 200 is supported in a horizontal orientation on the wafer lift pin 266 that protrudes from the surface of the susceptor 217.

When the wafer 200 is loaded into the process chamber 201, the first wafer transfer device 112 is discharged outside the process chamber 202, the predetermined gate valve is closed and an inside of the reaction container 203 is sealed. Then, when the susceptor 217 is raised, the wafer 200 is placed on each of the wafer placement portions 217b provided in the susceptor 217.

Also, when the wafer 200 is loaded into the process chamber 201, N₂ gas serving as the inert gas is preferably supplied into the process chamber 201 from the inert gas supply system while an inside of the process chamber 201 is exhausted by the exhaust system. That is, while the vacuum pump 246 is operated to open the APC valve 243 and the inside of the process chamber 201 is exhausted, N₂ gas is preferably supplied into the process chamber 201 by opening the valve 232d of at least a second gas supply unit 232. Accordingly, it is possible to suppress particles from being introduced into the process chamber 201 and particles from being attached onto the wafer 200. Also, the inert gas may be supplied from a third gas supply system. Also, the vacuum pump 246 is continuously operated at least until the substrate loading and placing process (S110) to a substrate unloading process (S170) to be described below are completed.

When the wafer 200 is placed on the susceptor 217, the surface of the wafer 200 is controlled to have a predetermined temperature by supplying power to the heater 218 that is embedded in the susceptor 217. The temperature of the wafer 200 is, for example, room temperature or more and 650° C. or less, and preferably, room temperature or more and 400° C. or less. In this case, a temperature of the heater 218 is regulated by controlling power supply to the heater 218 based on information on a temperature detected by the temperature sensor 249. Also, the heater 218 is continuously supplied with power until at least the substrate loading and placing process (S110) to a substrate unloading process (S170) to be described below are completed.

[Susceptor Rotation Start Process (S120)]

First, when the wafer 200 is placed on the wafer placement portion 217b, the susceptor 217 starts to rotate in an R direction by the rotating mechanism 267. In this case, a rotation speed of the susceptor 217 is controlled by the controller 300. The rotation speed of the susceptor 217 is, for example, 1 rpm or more and 100 rpm or less. Specifically, the rotation speed is, for example, 60 rpm. The controller 300 starts rotation of the rotating mechanism 267 such that the wafer 200 sequentially moves to the first processing region 206a, the first purge region 207a, the second processing region 206b and the second purge region 207b by rotating the susceptor 217.

[Gas Supply Start Process (S130)]

When the wafer 200 is heated to a desired temperature and the susceptor 217 reaches a desired rotation speed, the valve 231d is opened and supply of DCS gas into the first processing region 206a starts. At the same time, the valve 232d and a valve 232f are opened to supply NH₃ gas into the second processing region 206b.

In this case, the MFC 231c is regulated such that DCS gas has a predetermined flow rate. Also, DCS gas has a supply flow rate of, for example, 50 sccm or more and 500 sccm or less. Also, in addition to DCS gas, N₂ gas serving as a carrier gas may flow from an inert gas supply unit 234 of a first gas supply unit 231.

Also, the MFC 233c is regulated such that NH₃ gas has a predetermined flow rate. Also, NH₃ gas has a supply flow rate of, for example, 100 sccm or more and 5,000 sccm or less. Also, in addition to NH₃ gas, N₂ gas serving as a carrier gas or a dilution gas may flow from an inert gas supply unit 235 of a third gas supply unit.

Also, after the substrate loading and placing process (S110), an inside of the process chamber 201 is continuously exhausted by an exhaust part, and N₂ gas serving as a purge gas is supplied into the first purge region 207a and the second purge region 207b from the inert gas supply system. Also, by appropriately regulating a degree of opening of the APC valve 243, a pressure in the process chamber 201 is set to a predetermined pressure.

[Film Formation Process (S140)]

Next, the film formation process (S140) will be described. Here, a basic flow of the film formation process (S140) is described and details will be described below.

In the film formation process (S140), first, power is supplied to the coil 293. NH₃ gas supplied to a plasma generating space in plasma generating chamber 290 becomes a plasma state. In each of the wafers 200, a Si-containing layer is formed as the first layer in the first processing region 206a. Also, in the second processing region 206b, the Si-containing layer reacts with NH₃ plasma and thus the SiN film is formed on the wafer 200 as a second layer. Also, the susceptor 217 may rotate a predetermined number of times to obtain a desired film thickness.

[Gas Supply Stop Process (S150)]

The susceptor 217 is rotated a predetermined number of times to obtain a desired film thickness and then the valves 231d, 232d and 233d are closed to stop supply of DCS gas to the first processing region 206a, supply of NH₃ gas to the second processing region 206b and supply of the inert gas to a purge gas supply region.

In the film formation process (S140), when the valve 234d and the valve 235d are opened, the valve 234d and the valve 235d are closed to stop supply of the inert gas.

[Susceptor Rotation Stop Process (S160)]

After the gas supply stop process (S150), rotation of the susceptor 217 is stopped.

[Substrate Unloading Process (S170)]

Next, the susceptor 217 is lowered and the wafer 200 is supported on the wafer lift pins 266 that protrude from the surface of the susceptor 217. Then, the predetermined gate valve is opened and the wafer 200 is unloaded outside the reaction container 203 using the first wafer transfer device 112. Also, supply of N₂ gas serving as the inert gas into the process chamber 201 by the inert gas supply system is stopped.

Next, the film formation process (S140) will be described in detail with reference to FIG. 10. Also, from a process of passing through the first processing region 206a (S210) to a process of passing through the second purge region (S240), one substrate among the plurality of substrates placed on the susceptor 217 will be mainly described.

As illustrated in FIG. 10, in the film formation process (S140), the plurality of wafers 200 sequentially pass through the first processing region 206a, the first purge region 207a, the second processing region 206b and the second purge region 207b by rotation of the susceptor 217.

First, through the third gas supply pipe 233a, NH₃ gas is supplied to the plasma generating chamber 290 with the reactive gas inlet hole 292a therebetween. The supplied NH₃ gas collides with the gas dispersion plate 294a and spreads in a direction of the sidewall 291. The spread NH₃ gas is supplied to the vicinity of the coil 293 along the sidewall 291.

When the supplied NH₃ gas has a stable flow rate, the plasma generating chamber 290 starts to generate NH₃ plasma in the second processing region 206b. Specifically, when a pressure in the process chamber 201 is stable, the high frequency power source 298 starts to apply high frequency power to the coil 293.

Accordingly, a magnetic field is formed in plasma generating chamber 290. Induction plasma having a ring shape is excited at a height position that corresponds to the electrical midpoint of the coil 293 in plasma generating chamber 290. Plasma-phase NH₃ gas is dissociated and nitrogen active species containing nitrogen (N) and reactive species such as ions are generated.

As described above, a standing wave in which a phase voltage and a reverse phase voltage are constantly offset is formed and the highest phase current is generated at the electrical midpoint (a node having zero voltage) of the coil. Therefore, the induction plasma excited at the electrical midpoint has almost no capacitive coupling with the process chamber wall or the substrate placement unit. In plasma generating chamber 290, plasma having an extremely low electric potential and a ring shape may be formed.

Also, as described above, the power control device provided in the high frequency power source 298 compensates for a deviation of the resonance point of the coil 293 due to changes in capacitive coupling or inductive coupling of plasma and forms the standing wave more accurately. Therefore, it is possible to form plasma having almost no capacitive coupling and an extremely low electric potential more reliably in plasma generating space.

Since the plasma having an extremely low electric potential is generated, it is possible to prevent sheath from generating on a wall of the plasma generating chamber 290 and the substrate placement unit. Therefore, ions in plasma are not accelerated.

[Pass Through First Processing Region (S210)]

When the wafer 200 passes through the first processing region 206a, DCS gas is supplied to the wafer 200. In this case, since there is no reactive gas in the first processing region 206a, molecules of DCS gas do not react with the reactive gas and are directly attached (adhered) to the surface of the wafer 200. Accordingly, the first layer is formed on the surface of the wafer 200.

Here, the term “first layer” is a layer including any of Si atoms adhered to the wafer 200 when DCS gas is decomposed, some molecules of DCS gas, molecules of DCS gas that are undecomposed and adhered to the wafer 200, or binding molecules thereof.

Also, the term “first layer” collectively refers to, for example, a continuous layer containing Si, a discontinuous layer containing Si, or a thin film formed by stacking these layers. The continuous layer containing Si may also be called a thin film. Also, “layer having a thickness of less than one atomic layer” refers to a discontinuously formed atomic layer. “Layer having a thickness of one atomic layer” refers to a continuously formed atomic layer. When a thickness of the first layer formed on the wafer 200 is more than several atomic layers, a reaction or a modification action caused by plasma radiation of the reactive gas is not delivered to the entire first layer. Also, a minimum thickness value of the first layer that may be formed on the wafer 200 is less than one atomic layer. Therefore, preferably, the first layer has a thickness of less than one atomic layer to several atomic layers.

The first layer is formed to have a predetermined thickness and a predetermined distribution according to, for example, a pressure in the process chamber 201, a flow rate of DCS gas, a temperature of the susceptor 217 and a time (a processing time for the first processing region 206a) taken for passing through the first processing region 206a.

[Pass Through First Purge Region (S220)]

Next, the wafer 200 passes through the first processing region 206a and then moves to the first purge region 207a. When the wafer 200 passes through the first purge region 207a, DCS molecules or some DCS molecules that do not form a strong bond on the wafer 200 in the first processing region 206a are removed from the wafer 200 by N₂ gas serving as the inert gas.

[Pass Through Second Processing Region (S230)]

Next, the wafer 200 passes through the first purge region 207a and then moves to the second processing region 206b. When the wafer 200 passes through the second processing region 206b, the first layer reacts with plasma of NH₃ gas serving as the reactive gas in the second processing region 206b.

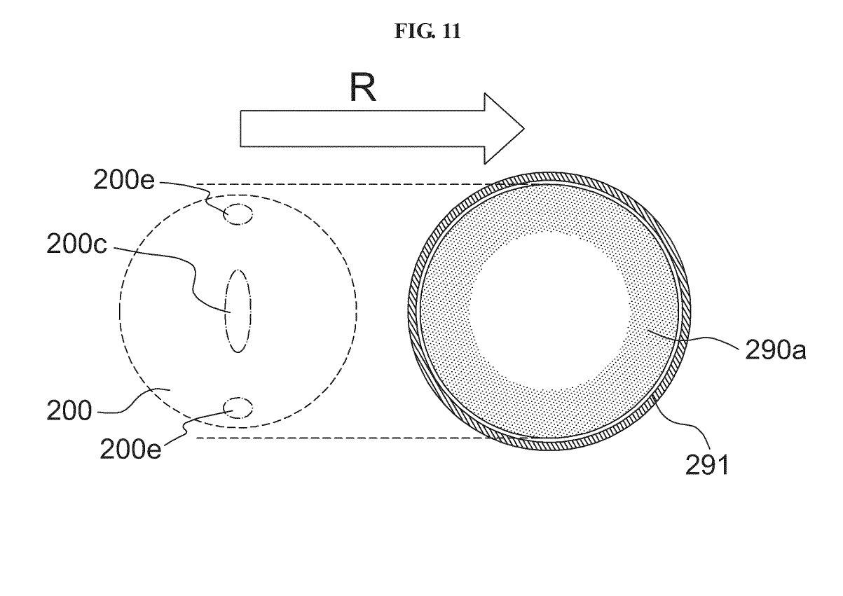

As described above, in plasma generating chamber 290, the plasma 290a having a ring shape is formed and the wafer 200 passes through therebelow. As illustrated in FIG. 11, the wafer 200 passes below an inner circumference of the sidewall 291 (the communication port 203a) in a horizontal direction.

Since the ring-shaped plasma 290a has a uniform density in a circumferential direction, an end 200e and a center portion 200c of the wafer 200 in a diameter direction are supplied with plasma of the same density compared to a Comparative Example to be described below. In other words, plasma is not generated in a center portion when plasma is radiated onto the wafer 200, plasma radiated onto the center portion of the wafer 200 is regulated and thus plasma radiated to the center portion of the wafer 200 and radiated to the end of the wafer 200 is equalized. As a result, through circular plasma, plasma of the same intensity is radiated into the surface of the wafer 200. Accordingly, it is considered that plasma of a certain amount or more that is necessary for nitridation of the Si-containing layer formed on the wafer 200 in the film formation is radiated. Therefore, a Si-containing film formed on the wafer 200 is uniformly treated by NH₃ plasma (plasma of the reactive gas).

In plasma treatment, N atoms among active species of NH₃ gas are bound to Si atoms of the first layer and H atoms among active species of NH₃ gas react with chlorine (Cl) atoms (chloro group) of the first layer, become HCl and are desorbed from the first layer. Therefore, the second layer containing at least Si and N is formed on the wafer 200.

Here, the term “second layer” refers to, for example, a layer that contains continuously or discontinuously arranged N atoms, nitrogen molecules, or NH₃ molecules that are bound to Si atoms and the like of a first layer on the continuously or discontinuously formed first layer, or a layer that contains N atoms, nitrogen molecules, or NH₃ molecules that bind with Si atoms and the like of the first layer in the continuously or discontinuously formed first layer.

The second layer is formed to have a predetermined thickness, a predetermined distribution, a penetration depth of predetermined N atoms with respect to the first layer and the like according to, for example, a pressure in the reaction container 203, a flow rate of NH₃ gas, a temperature of the susceptor 217, a power supply state of the reactive gas plasma generating unit 270a and the like.

[Pass Through Second Purge Region (S240)]

Next, the wafer 200 passes through the second processing region 206b and then moves to the second purge region 207b. When the wafer 200 passes through the second purge region 207b, HCl desorbed from the second layer containing at least Si and N on the 0.13 wafer 200 in the third processing region (not illustrated), extra H₂ gas and the like are removed from the wafer 200 by N₂ gas serving as the inert gas.

One cycle includes the passing through the first processing region (S210), the passing through the first purge region (S220), the passing through the second processing region (S230) and the passing through the second purge region (S240).

[Determination (S250)]

In the meantime, the controller 300 determines whether the one cycle is performed a predetermined number of times (k times: k is an integer of 1 or more). Specifically, the controller 300 counts the number of rotations of the susceptor 217.

When the one cycle is not performed k times (No in S250), rotation of the susceptor 217 is continued further and the cycle including the passing through the first processing region (S210), the passing through the first purge region (S220), the passing through the second processing region (S230) and the passing through the second purge region (S240) is repeated. Accordingly, the thin film is formed by laminating the second layer.

When the one cycle is performed k times (Yes in S250), the film formation process (S140) ends. In this manner, when the one cycle is performed k times, a thin film having a predetermined film thickness in which the second layer is laminated is formed.

In this manner, according to the present embodiment, when the Si-containing layer is formed by activating gas to plasma, it is possible to increase a throughput even at a low temperature, compared to a CVD method using no plasma. Also, when induction plasma of the present embodiment is used, plasma of a uniform density is generated in a direction perpendicular to the rotation direction of the substrate placement unit. Therefore, since plasma may be uniformly supplied onto the surface of the substrate, it is possible to form the SiN film of a high quality while maintaining a throughput at a low temperature. Also, the formed SiN film in the present embodiment may include a Si—N—H group (bond) by including H atoms of NH₃ gas serving as the reactive gas.

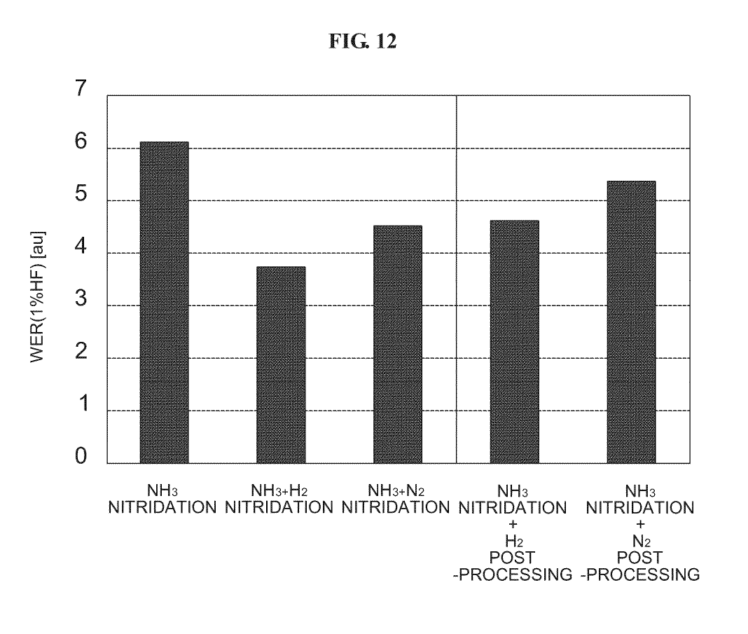

Also, while the present embodiment has exemplified the case in which NH₃ gas is used as the reactive gas, the present invention is not limited thereto. Here, other reactive gases will be described with reference to FIG. 12. FIG. 12 is a diagram illustrating a wet etch rate (hereinafter referred to as a WER) when each of the reactive gases is treated. Here, it is determined that a good film having a high film density is formed as the WER decreases.

In the drawing, in Example 1, “NH₃ nitridation” indicates that an SiN film is formed using NH₃ gas (ammonia gas) as the reactive gas. In Example 2, “NH₃+H₂ nitridation” indicates that an SiN film is formed using a mixed gas of NH₃ gas and H₂ (hydrogen) gas as the reactive gas. In Example 3, “NH₃+N₂ nitridation” indicates that an SiN film is formed using a mixed gas of NH₃ gas and N₂ (nitrogen) gas as the reactive gas.

In Example 4, “NH₃ nitridation+H₂ post-processing” indicates that a device having a structure in which a third processing region is further included in the vicinity of the second processing region is used for treatment, nitridation is performed using NH₃ gas in the second processing region and then the SiN film is modified (post-processed) using H₂ (hydrogen) gas in the third processing region. In Example 5, “NH₃ nitridation+N₂ post-processing” indicates that the device having a structure in which a third processing region is further included in the vicinity of the second processing region is used for treatments, nitridation is performed using NH₃ gas in the second processing region and then the SiN film is modified (post-processed) using N₂ (nitrogen) gas in the third processing region.

Here, “NH₃ nitridation” (Example 1) illustrated in FIG. 12 is the Example in the present embodiment (the first embodiment) described above and the process conditions include a substrate temperature of 200° C. to 650° C. (preferably, 250° C. to 450° C.), a susceptor rotation speed of 1 rpm to 100 rpm (preferably, 5 rpm to 60 rpm), for example, a rotation speed of 60 rpm, a source gas (DCS gas) of 10 sccm to 1,000 sccm (preferably, 100 sccm to 500 sccm), a reactive gas (NH₃ gas) of 100 sccm to 10,000 sccm (preferably, 5,000 sccm to 10,000 sccm), and high frequency power of 0.1 kW to 5,000 kW (preferably, 1,000 kW to 4,000 kW).

Also, Examples 2 and 3 have the same process conditions as Example 1 except that a different reactive gas is used (Example 2 uses a mixed gas of NH₃ and H₂ and Example 3 uses a mixed gas of NH₃ and N₂). In Example 2, the reactive gas (a mixed gas of NH₃ and H₂) has a flow rate of 100 sccm to 10,000 sccm (preferably, 5,000 sccm to 10,000 sccm). In Example 3, the reactive gas (a mixed gas of NH₃ and N₂) has a flow rate of 100 sccm to 10,000 sccm (preferably, 5,000 sccm to 10,000 sccm).

Also, Examples 4 and 5 have the same process conditions as Example 1 except that a modification process is added after the reactive gas (NH₃) is supplied. Here, in Example 4, the modifying gas (H₂ gas) has a flow rate of 100 sccm to 10,000 sccm (preferably, 5,000 sccm to 10,000 sccm). In Example 5, the modifying gas (N₂ gas) has a flow rate of 100 sccm to 10,000 sccm (preferably, 5,000 sccm to 10,000 sccm).

As illustrated in FIG. 12, it can be understood that, compared to “NH₃ nitridation” in Example 1, when the mixed gas (a mixed gas of NH₃ and H₂ and a mixed gas of NH₃ and N₂) is added in the second processing region as in Examples 2 and 3 or when the third processing region is further added and the modifying gas (H₂ gas and N₂ gas) is supplied to perform the modification process as in Examples 4 and 5, it is possible to form a good film having a higher density. Also, when the modification process is added as in Examples 4 and 5, the processing region is preferably divided into six regions (the first processing region 206a, the first purge region 207a, the second processing region 206b, the second purge region 207b, the third processing region 206c and a third purge region 207c) by the partition plate 205. In this case, the first processing region 206a forms a source gas supply region, the second processing region 206b forms a reactive gas supply region and the third processing region 206c forms a post-processing (modifying) gas supply region. In addition, the processing region may be divided into 5 regions (the first processing region 206a, the first purge region 207a, the second processing region 206b, the third processing region 206c and a third purge region 207c) by omitting the second purge region 207b when third processing region 206c is added.

Here, it is needless to say that combinations such as “NH₃+H₂+N₂ nitridation” (Example 6), “NH₃+H₂ nitridation+H₂ post-processing” (Example 7), “NH₃+H₂ nitridation+N₂ post-processing” (Example 8), “NH₃+N₂ nitridation+H₂ post-processing” (Example 9) and “NH₃+H₂ nitridation+H₂ post-processing” (Example 10) are effective reactive gases, in addition to Examples 1 to 5.

Also, in Examples 4, 5 and 7 to 10, in the post-processing (modification process), the post-processing (modifying) gas may be activated (for example, become a plasma state). In this case, the present invention is not limited to high frequency power in the present embodiment. For example, microwave power may be used to activate the modifying gas to plasma.

### Description of Comparative Example

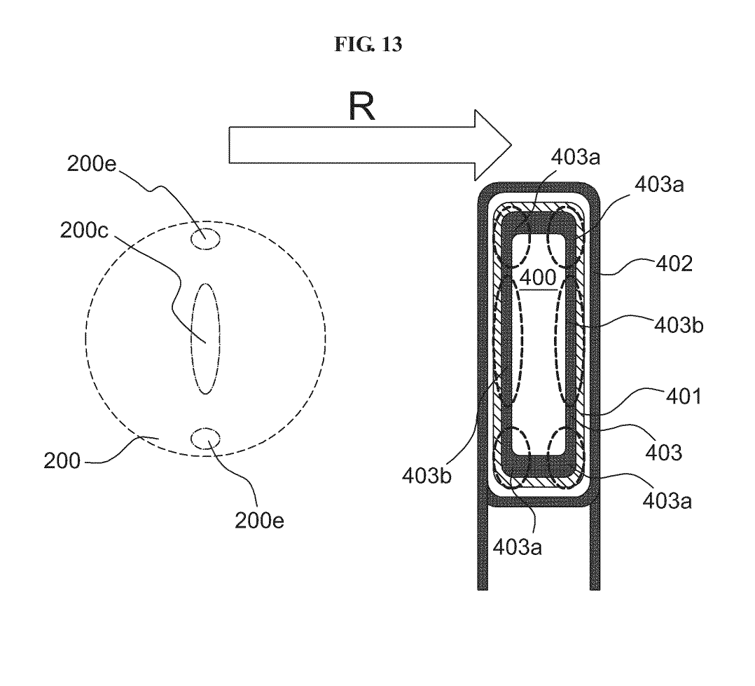

Next, the Comparative Example of the first embodiment will be described with reference to FIG. 13. The Comparative Example has the same configuration as the first embodiment except that a plasma generating unit is provided above the second processing region. Hereinafter, the plasma generating unit of the Comparative Example will be described.

In FIG. 13, reference numeral 401 indicates a sidewall of a plasma generating unit 400 in the Comparative Example, reference numeral 402 indicates a coil wound on an outer circumference of the sidewall 401 and reference numeral 403 is plasma that is formed using the coil 402. A high frequency power source and the like are connected to the coil 402, similar to the first embodiment.

The sidewall 401 has a rectangular shape when seen from the top. In order to supply plasma to an edge portion of the wafer 200 that passes below the plasma generating unit 400, a long side of the sidewall 401 is set to be greater than a diameter of the wafer. Also, from the perspective of a small size, a short side direction of the sidewall 401 is set to be smaller.

The coil 402 has a rectangular shape matching the sidewall. Therefore, unlike the coil 293 of the first embodiment, a part adjacent to the sidewall 401 has no constant curvature. Specifically, a part transiting from the long side to the short side of the coil 402 has a higher curvature than the long side and the short side.

When plasma is generated, power is supplied from the high frequency power source (not illustrated). Plasma is generated by the generated magnetic field and the like. In general, the magnetic field is known to be formed in a direction perpendicular to a conductive line of the coil 402. In the Comparative Example, since the magnetic field is concentrated on a bent portion from the long side to the short side, the bent portion has a higher magnetic field density than the long side. Since a density of the magnetic field is proportional to a density of plasma, the plasma density of the bent portion is greater than the plasma density of the long side portion. That is, in FIG. 13, a plasma 403a has a higher density than a plasma 403b.

Under such circumstances, when the wafer 200 rotates in the R direction and passes below the plasma generating unit, a reaction of the wafer edge portion 200e in contact with the plasma 403a is facilitated more than that of the wafer center portion 200c in contact with the plasma 403b. Therefore, the wafer edge portion 200e and the wafer center portion 200c have a different film quality such as a film density.

On the contrary, in the first embodiment, since densities of plasmas in contact with the wafer center portion 200c and the wafer edge portion 200e are the same, it is possible to set the wafer edge and the center portion to have a desired range of a film quality such as a film density.

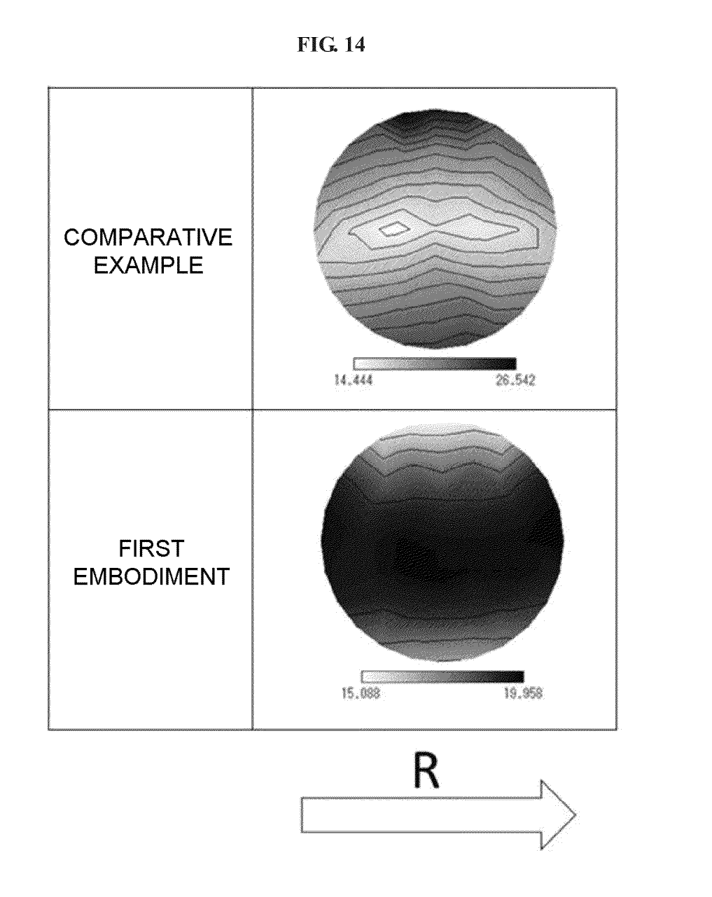

FIG. 14 is a characteristic diagram illustrating a comparison of uniformities of the present embodiment (the first embodiment) and the Comparative Example illustrated in FIG. 13. In the characteristic diagram, larger film thicknesses are shown in darker colors and smaller film thicknesses are shown in bright colors. A rotation direction R of the wafer is a left to right direction in the drawing.

As illustrated in FIG. 14, in the Comparative Example, it can be understood that the center has a small film thickness and the wafer edge portion has a large film thickness.

Meanwhile, it can be understood that the first embodiment of the present invention has a more uniform in-plane film thickness of the substrate than the Comparative Example.

Also, as illustrated in FIG. 14, in the Comparative Example, since a maximum value of the film thickness is 26.542 nm and a minimum value thereof is 14.444 nm, maximum value−minimum value=12.098 nm. Meanwhile, in the first embodiment of the present invention, since a maximum value of the film thickness is 19.958 nm and a minimum value thereof is 15.088 nm, maximum value−minimum value=4.870 nm. Therefore, it can be understood that the present embodiment (the first embodiment) has a more uniform in-plane film thickness of the substrate than the Comparative Example (the substrate surface has a small unevenness).

### (4) Effects According to the Present Embodiment

According to the present embodiment, one or a plurality of effects to be described below are obtained.

(a) According to the present embodiment, since the coil adjacent to the plasma generating unit has a constant curvature, circular plasma of a uniform density may be generated in a circumferential direction. Therefore, even when the susceptor rotates, plasma radiated to the center portion of the substrate may be regulated. As a result, plasma may be uniformly supplied in a diameter direction of the substrate.

(b) According to the present embodiment, when DCS gas is used the source gas and a mixed gas of NH₃ gas and H₂ gas is used as the reactive gas to form the SiN film as a thin film, the result of the best film density was obtained. In this case, (in Example 2), when the wafer 200 passes through the second processing region 206b, Cl atoms (chloro group) serving as residues remaining in the second layer become HCl by plasma of H₂ gas and are desorbed from the second layer. Accordingly, it is possible to form the SiN film of a high quality by laminating the second layer in which CI atoms are decreased.

(c) According to the present embodiment, the plurality of partition plates 205 are configured to divide the process chamber 201 into the first processing region 206a, the second processing region 206b and the third processing region 206c while the wafer 200 can pass through by rotation of the susceptor 217. The process chamber 201 includes a gap through which the wafer 200 can pass below the plurality of partition plates 205. Accordingly, an amount of a gas that passes between the partition plate 205 and the susceptor 217 decreases and mixing of the gases between the regions in the process chamber 201 is suppressed.

### Other Embodiments of the Present Invention

While the embodiments of the present invention have been specifically described above, the present invention is not limited to the above-described embodiments, but may be variously modified without departing from the scope of the invention.

The above-described embodiments have described the case in which the gap is provided between an end of the partition plate 205 in a horizontal direction and the sidewall of the reaction container 203 and a pressure in the process chamber 201 is the same in each of the regions. However, the first processing region 206a, the first purge region 207a, the second processing region 206b and the second purge region 207b may be hermetically divided. Also, the pressure in each of the regions may be different.

Also, the above-described embodiments have described the case in which the five wafers 200 are processed by the one process chamber 202. However, the one wafer 200 or more than five wafers 200 may be processed by the one process chamber 202.

Also, the above-described embodiments have described the case in which the spare chamber 122 or the spare chamber 123 is configured to have functions of both loading the wafer 200 and unloading the wafer 200. However, one of the spare chamber 122 and the spare chamber 123 may be provided for unloading and the other thereof may be provided for loading. When the spare chamber 122 or the spare chamber 123 is dedicated for loading or unloading, cross contamination may be decreased. When the functions of both loading and unloading are provided, transfer efficiency of the substrate may be increased.

Also, the above-described embodiments have described substrate processing in the one process chamber 202, but processing in each of the process chambers may be concurrently performed.

Also, the above-described embodiments have described the case in which the four process chambers 202 have the same configuration. However, each of the process chambers may have a different configuration and each of the process chambers may perform a separate process. For example, when the first process chamber and the second process chamber perform different processes, a predetermined process is performed on the wafer 200 by the first process chamber and then a process different from that of the first process chamber may be performed by the second process chamber. Also, when a predetermined process is performed on the substrate by the first process chamber and then a different process is performed by the second process chamber, the spare chamber may be passed through.

Also, the above-described embodiments have described the case in which DCS gas is used as the source gas and NH₃ gas is used as the reactive gas to form the SiN film on the wafer 200 as a nitride film. However, as the source gas, in addition to DCS gas, for example, an inorganic source gas such as monochlorosilane (SiH₃Cl, abbreviated to: MCS) gas, hexachlorodisilane (Si₂Cl, abbreviated to: HCDS) gas, tetrachlorosilane, that is, silicon tetrachloride (SiCl₄, abbreviated to: STC) gas, trichlorosilane (SiHCI₃, abbreviated to: TCS) gas, tetrafluorosilane (SiF₄, abbreviated to: TFS) gas, hexafluoro disilane (Si₂F₆, abbreviated to: HFDS) gas, trisilane (Si₃H₈, abbreviated to: TS) gas, disilane (Si₂H, abbreviated to: DS) gas or monosilane (SiH₄, abbreviated to: MS) gas, or an organic source gas such as aminosilane, TSA gas, tetrakis(dimethylamino)silane (Si[N(CH₃)₂]₄, abbreviated to: 4DMAS) gas, tris(dimethylamino)silane (Si[N(CH₃)₂]₃H, abbreviated to: 3DMAS) gas, bis(diethylamino)silane (Si[N(C₂H₅)₂]₂H₂, abbreviated to: BDEAS) gas or bis(tertiary-butylamino)silane (SiH₂[NH(C₄H₉)]₂, abbreviated to: BTBAS) gas may be used.

As the reactive gas, in addition to ammonia gas, for example, a nitride hydrogen-based gas such as diazene (N₂H₂) gas, hydrazine (N₂H₄) gas or N₃H₈ gas, or a gas containing a compound thereof may be used.

Also, as the reactive gas, oxygen (O₂) gas may be used to form an oxide film. As an O-containing gas, in addition to O₂ gas, for example, nitrous oxide (N₂O) gas, nitric oxide (NO) gas, nitrogen dioxide (NO₂) gas, ozone (O₃) gas, a mixed gas of hydrogen (H₂) gas and O₂ gas, a mixed gas of H₂ gas and O₃ gas, water vapor (H₂O), carbon monoxide (CO) gas, carbon dioxide (CO₂) gas and the like may be used.

Also, other nitride films such as TaN and TiN, an oxide film such as HfO, ZrO and SiO and a metal film such as Ru, Ni and W may be formed on the wafer 200. Also, when a TiN film or a TiO film is formed, for example, titanium tetrachloride (TiCl₄) or the like may be used as the source gas.

Also, the above-described embodiments have described the case in which the inert gas inlet 282 is shared by the first purge region 207a and the second purge region 207b. However, the inert gas inlet may be individually provided.

Also, the above-described embodiments have described the case in which each gas is supplied into each of the processing regions through the center of the reaction container 203. However, a nozzle configured to supply a gas to each of the processing regions may be provided.

Also, the above-described embodiments have described the case in which the lifting mechanism 268 is used to lift the susceptor 217 such that the wafer 200 moves to a process position or a transfer position. However, the wafer may be moved to the process position or the transfer position by lifting the wafer lift pin.

Also, the above-described embodiments have described the case in which the first purge region 207a is provided between the first processing region 206a and the second processing region 206b. However, a position in which the purge region is provided may be changed arbitrarily. For example, at least one of the first purge region and the second purge region may be omitted.

Also, the above-described embodiments have described the case in which the processing gas is supplied into each of the processing regions through an gas inlet 280 provided at the center portion of the ceiling portion of the reaction container 203 and the plurality of gas outlets included in plasma generating units. However, the processing gas may be supplied into each of the processing regions through at least any of the gas inlet provided at the center portion of the ceiling portion of the reaction container and the plurality of gas outlets included in plasma generating units.

Also, the above-described embodiments have described the case in which there are four processing regions and the regions have the same area (angles between the partition plates 205 are the same). However, according to each process condition, areas of the regions may be set arbitrarily.

According to the present invention, a configuration in which plasma may be uniformly supplied to a substrate in a rotary apparatus is provided.

### PREFERRED EMBODIMENTS OF THE PRESENT INVENTION

Hereinafter, preferred embodiments according to the present invention are supplementarily noted.

### Supplementary Note 1

According to an aspect of the present invention, there is provided a substrate processing apparatus including:

a process chamber including a source gas supply region and a reactive gas supply region and configured to process a plurality of substrates in the source gas supply region and the reactive gas supply region;

a substrate placement unit capable of rotating in the process chamber, wherein the plurality of substrates are placed on the substrate placement unit along a rotational direction thereof;

a plasma generating unit configured to generate plasma in plasma generation chamber installed at an upper portion of the reactive gas supply region;

a coil wound along an outer circumference of the plasma generation chamber, wherein a portion of the coil adjacent to a sidewall of the plasma generation chamber has a constant curvature;

a reactive gas supply system configured to supply a reactive gas to the reactive gas supply region via the plasma generation chamber through a ceiling of the plasma generation chamber; and

a source gas supply system configured to supply a source gas to the source gas supply region.

### Supplementary Note 2

In the substrate processing apparatus of Supplementary note 1, preferably, further including a waveform adjusting circuit connected to the coil, and wherein a sum of electrical lengths of the waveform adjusting circuit and the coil is a multiple of a wavelength of a power applied to the coil.

### Supplementary Note 3

In the substrate processing apparatus of any one of Supplementary notes 1 and 2, preferably, the plasma generation chamber further includes a gas dispersion plate disposed between an upper end of the coil and the ceiling of the plasma generation chamber.

### Supplementary Note 4

In the substrate processing apparatus of any one of Supplementary notes 1 through 3, preferably, further including a communication hole disposed between the plasma generation chamber and the reactive gas supply region, and a diameter of the communication hole is greater than those of the plurality of substrates placed on the substrate placement unit, and the plurality of substrates passes under the communication hole when the substrate placement unit rotates.

### Supplementary Note 5

In the substrate processing apparatus of Supplementary note 1, preferably, further including:

a power supply unit configured to apply high frequency power to the coil;

a rotation unit (rotation mechanism) configured to rotate the substrate placement unit; and

a control unit configured to control the rotation unit to pass the plurality of substrates through the source gas supply region and the reactive gas supply region in sequence by rotating the substrate placement unit and configured to control the power supply unit, the plasma generating unit, the source gas supply system and the reactive gas supply system to form: a first layer on the plurality of substrates by supplying the source gas to the plurality of substrates while the plurality of substrates passes through the source gas supply region; and a second layer by reacting the first layer with the plasma generated by the plasma generating unit while the plurality of substrates passes through the reactive gas supply region.

### Supplementary Note 6

In the substrate processing apparatus of Supplementary note 1, preferably, further including:

a power supply unit configured to apply high frequency power to the coil;

a rotation unit (rotation mechanism) configured to rotate the substrate placement unit;

a post-processing gas supply system configured to supply a post-processing gas to a post-processing gas supply region; and

a control unit configured to control the rotation unit to pass the plurality of substrates through the source gas supply region, the reactive gas supply region and the post-processing gas supply region in sequence by rotating the substrate placement unit and configured to control the power supply unit, the plasma generating unit, the source gas supply system, the reactive gas supply system and the post-processing gas supply system to form: a first layer on the plurality of substrates by supplying the source gas to the plurality of substrates while the plurality of substrates passes through the source gas supply region and a second layer by reacting the first layer with the plasma generated by the plasma generating unit while the plurality of substrates passes through the reactive gas supply region; and to modify the second layer with the post-processing gas while the plurality of substrates passes through the post-processing gas supply region.

### Supplementary Note 7

In the substrate processing apparatus of any one of Supplementary notes 1, 5 and 6, preferably, the reactive gas includes at least one selected from the group consisting of NH₃ gas, a mixture gas of NH₃ and H₂, a mixture gas of NH₃ and N₂ and a mixture gas of NH₃, H₂ and N₂.

### Supplementary Note 8

In the substrate processing apparatus of Supplementary note 6, preferably, the post-processing gas includes at least one selected from the group consisting of H₂ gas, N₂ gas and a mixture gas of H₂ and N₂.

### Supplementary Note 9

In the substrate processing apparatus of any one of Supplementary notes 1, 5 and 6, preferably, the source gas includes at least one selected from the group consisting of DCS gas, MCS gas, HCDS gas, STC gas, TCS gas, TFS gas, HFDS gas, TS gas, DS gas and MS gas.

### Supplementary Note 10

In the substrate processing apparatus of any one of Supplementary notes 1, 5 and 6, preferably, the source gas includes at least one selected from the group consisting of titanium (Ti), tantalum (Ta), silicon (Si), hafnium (Hf), zirconium (Zr), ruthenium (Ru), nickel (Ni) and tungsten (W).

### Supplementary Note 11

In the substrate processing apparatus of any one of Supplementary notes 1, 5 and 6, preferably, the reactive gas includes at least one selected from the group consisting of N₂H₂ gas, N₂H₄ gas, N₃H gas and chemical compounds thereof.

### Supplementary Note 12

According to another aspect of the present invention, there is provided a method of manufacturing a semiconductor device including:

placing a plurality of substrates on a substrate placement unit capable of rotating in a process chamber along a direction of rotation;

supplying a source gas to a source gas supply region of the process chamber by a source gas supply system and supplying a reactive gas to a reactive gas supply region of the process chamber by a reactive gas supply system via a plasma generating chamber installed in a ceiling of the reactive gas supply region;

applying power to a coil wound along an outer circumference of the plasma generation chamber, wherein a portion of the coil adjacent to a sidewall of the plasma generation chamber has a constant curvature to process the plurality of substrates with the reactive gas in plasma state; and

rotating the substrate placement unit so that the plurality of substrates pass through the source gas supply region and the reactive gas supply region in sequence.

### Supplementary Note 13

According to still another aspect of the present invention, there is provided a method of manufacturing a semiconductor device including:

(a) providing (preparing) a substrate processing apparatus including: a substrate placement unit including a substrate placing surface, wherein a plurality of substrates are placed on the substrate placing surface along a circumferential direction of the substrate placing surface; a rotation unit configured to rotate the substrate placement unit along a rotational direction parallel to the substrate placing surface; a process chamber including a source gas supply region and a reactive gas supply region and configured to supply a source gas and a reactive gas, respectively; a coil, wherein a portion of the coil adjacent to a sidewall of the process chamber has a constant curvature; a reactive gas supply system configured to supply the reactive gas to the reactive gas supply region via a plasma generation chamber installed at an upper portion of the reactive gas supply region; and a source gas supply system connected to a ceiling of the source gas supply region and configured to supply the source gas to the source gas supply region;

(b) placing the plurality of substrates on the substrate placing surface;

(c) supplying the source gas to the source gas supply region and the reactive gas to the reactive gas supply region;

(d) applying power to the coil to generate the reactive gas in plasma state; and

(e) rotating the substrate placement unit to supply the source gas and the reactive gas in plasma state in sequence to the plurality of substrates to process the plurality of substrates.

### Supplementary Note 14

According to still another aspect of the present invention, there is provided a program or a non-transitory computer-readable recording medium storing a program for causing a computer to perform:

(a) placing a plurality of substrates on a substrate placing surface of a substrate processing apparatus, wherein the substrate processing apparatus including: a substrate placement unit including the substrate placing surface, wherein a plurality of substrates are placed on the substrate placing surface along a circumferential direction of the substrate placing surface; a rotation unit configured to rotate the substrate placement unit along a rotational direction parallel to the substrate placing surface; a process chamber including a source gas supply region and a reactive gas supply region and configured to supply a source gas and a reactive gas, respectively, along the rotational direction; a plasma generation chamber installed at an upper portion of the reactive gas supply region; a coil, wherein a portion of the coil adjacent to a sidewall of the process chamber has a constant curvature; a reactive gas supply system configured to supply the reactive gas to the reactive gas supply region via the plasma generation chamber; and a source gas supply system configured to supply the source gas to the source gas supply region;

(b) supplying the source gas to the source gas supply region and the reactive gas to the reactive gas supply region;

(c) applying power to the coil to generate the reactive gas in plasma state; and

(d) rotating the substrate placement unit to supply the source gas and the reactive gas in plasma state in sequence to the plurality of substrates to process the plurality of substrates.

### Supplementary Note 15

A non-transitory computer-readable recording medium storing a program executed in a substrate processing apparatus, the substrate processing apparatus comprising: a substrate placement unit comprising a substrate placing surface, wherein a plurality of substrates are placed on the substrate placing surface along a circumferential direction of the substrate placing surface; a rotation unit configured to rotate the substrate placement unit along a rotational direction parallel to the substrate placing surface; a process chamber comprising a source gas supply region and a reactive gas supply region; a plasma generating unit configured to generate plasma in plasma generation chamber installed at an upper portion of the reactive gas supply region; a coil wound along an outer circumference of the plasma generation chamber, wherein a portion of the coil adjacent to a sidewall of the plasma generation chamber has a constant curvature; a reactive gas supply system connected to a ceiling of the plasma generation chamber and configured to supply the reactive gas to the reactive gas supply region via the plasma generation chamber; a source gas supply system connected to a ceiling of the source gas supply region and configured to supply the source gas to the source gas supply region; and a control unit configured to control the rotation unit, the plasma generating unit, the source gas supply system, and the reactive gas supply system, the program causing the substrate processing apparatus to perform:

(a) placing a plurality of substrates on a substrate placement unit capable of rotating in a process chamber;

(b) supplying a source gas to a source gas supply region of the process chamber and supplying a reactive gas to a reactive gas supply region of the process chamber;

(c) supplying electric power to the coil to excite the reactive gas in plasma state;

(d) rotating the substrate placement unit so that the plurality of substrates pass through the source gas supply region and the reactive gas supply region in sequence.

What is claimed is:

1. A substrate processing apparatus comprising:
a process chamber comprising a source gas supply region and a reactive gas supply region and configured to process a plurality of substrates in the source gas supply region and the reactive gas supply region;
a substrate placement unit capable of rotating in the process chamber, wherein the plurality of substrates are placed on the substrate placement unit along a rotational direction thereof;
a plasma generating unit configured to generate plasma in plasma generation chamber installed at an upper portion of the reactive gas supply region;
a coil wound along an outer circumference of the plasma generation chamber, wherein a portion of the coil adjacent to a sidewall of the plasma generation chamber has a constant curvature;
a reactive gas supply system configured to supply a reactive gas to the reactive gas supply region via the plasma generation chamber through a ceiling of the plasma generation chamber; and
a source gas supply system configured to supply a source gas to the source gas supply region.

2. The substrate processing apparatus of claim 1, further comprising a waveform adjusting circuit connected to the coil, and wherein a sum of electrical lengths of the waveform adjusting circuit and the coil is a multiple of a wavelength of a power applied to the coil.

3. The substrate processing apparatus of claim 1, wherein plasma generation chamber further comprises a gas dispersion plate disposed between an upper end of the coil and the ceiling of the plasma generation chamber

4. The substrate processing apparatus of claim 1, wherein further comprising a communication hole disposed between the plasma generation chamber and the reactive gas supply region, and wherein a diameter of the communication hole is greater than those of the plurality of substrates placed on the substrate placement unit, and the plurality of substrates passes under the communication hole when the substrate placement unit rotates.

5. The substrate processing apparatus of claim 1, further comprising:
a rotation unit configured to rotate the substrate placement unit; and
a control unit configured to control the rotation unit, the plasma generating unit, the source gas supply system and the reactive gas supply system to pass the plurality of substrates through the source gas supply region and the reactive gas supply region in sequence by rotating the substrate placement unit and to form: a first layer on the plurality of substrates by supplying the source gas to the plurality of substrates while the plurality of substrates passes through the source gas supply region; and a second layer by reacting the first layer with the plasma generated by the plasma generating unit while the plurality of substrates passes through the reactive gas supply region.

6. The substrate processing apparatus of claim 1, further comprising:
a rotation unit configured to rotate the substrate placement unit;
a post-processing gas supply system configured to supply a post-processing gas to a post-processing gas supply region; and
a control unit configured to control the rotation unit, the plasma generating unit, the source gas supply system, the reactive gas supply system and the post-processing gas supply system to pass the plurality of substrates through the source gas supply region, the reactive gas supply region and the post-processing gas supply region in sequence by rotating the substrate placement unit, to form: a first layer on the plurality of substrates by supplying the source gas to the plurality of substrates while the plurality of substrates passes through the source gas supply region and a second layer by reacting the first layer with the plasma generated by the plasma generating unit while the plurality of substrates passes through the reactive gas supply region; and to modify the second layer with the post-processing gas while the plurality of substrates passes through the post-processing gas supply region.

7. The substrate processing apparatus of claim 1, wherein the reactive gas comprises at least one selected from the group consisting of NH₃ gas, a mixture gas of NH₃ and H₂, a mixture gas of NH₃ and N₂ and a mixture gas of NH₃, H₂ and N₂.

8. The substrate processing apparatus of claim 6, wherein the post-processing gas comprises at least one selected from the group consisting of H₂ gas, N₂ gas and a mixture gas of H₂ and N₂.

9. The substrate processing apparatus of claim 1, wherein the source gas comprises at least one selected from the group consisting of DCS gas, MCS gas, HCDS gas, STC gas, TCS gas, TFS gas, HFDS gas, TS gas, DS gas and MS gas.

10. The substrate processing apparatus of claim 1, wherein the source gas contains at least one selected from the group consisting of titanium, tantalum, silicon, hafnium, zirconium, ruthenium, nickel and tungsten.

11. The substrate processing apparatus of claim 1, wherein the reactive gas comprises at least one selected from the group consisting of N₂H₂ gas, N₂H₄ gas, N₃H₈ gas and chemical compounds thereof.

12. A method of manufacturing a semiconductor device comprising:
placing a plurality of substrates on a substrate placement unit capable of rotating in a process chamber along a direction of rotation;
supplying a source gas to a source gas supply region of the process chamber and supplying a reactive gas to a reactive gas supply region of the process chamber via a plasma generation chamber installed in a ceiling of the reactive gas supply region; applying power to a coil wound along an outer circumference of the plasma generation chamber, wherein a portion of the coil adjacent to a sidewall of the plasma generation chamber has a constant curvature to process the plurality of substrates with the reactive gas in plasma state; and
rotating the substrate placement unit so that the plurality of substrates pass through the source gas supply region and the reactive gas supply region in sequence.

13. A non-transitory computer-readable recording medium storing a program executed in a substrate processing apparatus, the substrate processing apparatus comprising: a substrate placement unit comprising a substrate placing surface, wherein a plurality of substrates are placed on the substrate placing surface along a circumferential direction of the substrate placing surface; a rotation unit configured to rotate the substrate placement unit along a rotational direction parallel to the substrate placing surface; a process chamber comprising a source gas supply region and a reactive gas supply region; a plasma generating unit configured to generate plasma in plasma generation chamber installed at an upper portion of the reactive gas supply region; a coil wound along an outer circumference of the plasma generation chamber, wherein a portion of the coil adjacent to a sidewall of the plasma generation chamber has a constant curvature; a reactive gas supply system connected to a ceiling of the plasma generation chamber and configured to supply the reactive gas to the reactive gas supply region via the plasma generation chamber, a source gas supply system connected to a ceiling of the source gas supply region and configured to supply the source gas to the source gas supply region; and a control unit configured to control the rotation unit, the plasma generating unit, the source gas supply system, and the reactive gas supply system, the program causing the substrate processing apparatus to perform:
(a) placing a plurality of substrates on a substrate placement unit capable of rotating in a process chamber;
(b) supplying a source gas to a source gas supply region of the process chamber and supplying a reactive gas to a reactive gas supply region of the process chamber; (c) supplying electric power to the coil to excite the reactive gas in plasma state; and
(d) rotating the substrate placement unit so that the plurality of substrates pass through the source gas supply region and the reactive gas supply region in sequence.
